(19) United States
(12) Patent Application Publication
(10) Pub. No.: US 2024/0368393 A1
(43) Pub. Date: Nov. 7, 2024

(54) RESIN COMPOSITION FOR FORMING ETCHING MASK PATTERN, AND METHOD FOR MANUFACTURING ETCHING MASK PATTERN

(71) Applicants: TOKYO OHKA KOGYO CO., LTD., Kawasaki-shi (JP); TOKYO INSTITUTE OF TECHNOLOGY, Tokyo (JP)

(72) Inventors: Takehiro Seshimo, Kawasaki-shi (JP); Ken Miyagi, Kawasaki-shi (JP); Takahiro Dazai, Tokyo (JP); Teruaki Hayakawa, Tokyo (JP); Shinsuke Maekawa, Tokyo (JP); Ryota Uehara, Tokyo (JP)

(21) Appl. No.: 18/645,876

(22) Filed: Apr. 25, 2024

(30) Foreign Application Priority Data
May 1, 2023 (JP) 2023-075758
Dec. 22, 2023 (JP) 2023-216944
Apr. 17, 2024 (JP) 2024-066934

(51) Int. Cl. C08L 53/00

(52) U.S. Cl. CPC C08L 53/00

(57) ABSTRACT

A resin composition for forming an etching mask pattern containing a block copolymer having a first block and a second block, and a homopolymer having a number-average molecular weight of less than 3,000. The first block is a polymer of a constitutional unit represented by Formula (b1) and the second block is a random copolymer of a constitutional unit represented by Formula (b2m) and a constitutional unit represented by Formula (b2g). The proportion of the volume of the first block is 20% to 80% by volume. The homopolymer includes a polymer of the constitutional unit represented by Formula (b1). In the formulas illustrated below, R¹ is an alkyl group, R^{b1} is a hydrogen atom or a methyl group, n is an integer of 0 to 5, R² is an alkyl group, R³ is an alkylene group, R^{b2} is a hydrogen atom or the like, and x is more than 0 and less than 1

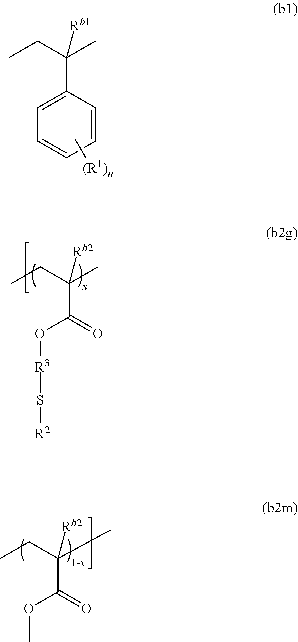

### BACKGROUND OF THE INVENTION

### Field of the Invention

The present invention relates to a resin composition for forming an etching mask pattern and a method for manufacturing an etching mask pattern.

Priority is claimed on Japanese Patent Application No. 2023-075758, filed on May 1, 2023, Japanese Patent Application No. 2023-216944, filed on Dec. 22, 2023, and Japanese Patent Application No. 2024-066934, filed on Apr. 17, 2024, the contents of which are incorporated herein by reference.

### Description of Related Art

In recent years, along with further miniaturization of large-scale integrated circuits (LSI), a technology for processing finer structure bodies has been demanded.

In response to such a demand, there has been developed a technology for forming a finer pattern by utilizing a phase-separated structure formed by self-organization of a block copolymer in which blocks incompatible to each other are bonded together (for example, see Japanese Unexamined Patent Application, First Publication No. 2008-36491).

In order to utilize the phase-separated structure of the block copolymer, it is considered essential to form self-organized nanostructures, which are formed by micro-phase separation, only in a specific region and arrange the nanostructures in a desired direction. In order to realize the position control and orientation control of these nanostructures, processes such as graphoepitaxy for controlling the phase separation pattern by a guide pattern, and chemical epitaxy for controlling the phase separation pattern by the difference in the chemical state of the substrate, have been proposed (for example, see Proceedings of SPI, Vol. 7637, No. 76370G-1 (2010)).

The block copolymer forms a structure body having a regular periodic structure by the phase separation.

The phrase “period of a structure body” means the period of the phase structure observed when the structure body of a phase-separated structure is formed and refers to the sum of the lengths of the phases each of which is incompatible. In a case where the phase-separated structure forms a cylinder structure perpendicular to a surface of the substrate, the period (L0) of the structure body is a distance (pitch) between centers of two adjacent cylinder structures.

It is known that the period (L0) of the structure body is determined by inherent polymerization properties such as the degree of polymerization N and interaction parameter χ of Flory-Huggins. That is, as the product “χ×N” of χ and N is larger, the mutual repulsion between the different blocks in the block copolymer is greater. Therefore, in a case of the relation of χ×N>10.5 (hereinafter, referred to as “strong separation limit”), the repulsion between the different kinds of blocks in the block copolymer is large, and the tendency for phase separation to occur is strong. Accordingly, in the strong separation limit, the period of the structure body is approximately N^{2/3}×χ^{1/6}, and satisfies the relationship of the following expression (1). That is, the period of the structure body is proportional to the degree of polymerization N, which correlates with the molecular weight and the molecular weight ratio between the different blocks.

$$L 0 ∝ a \times {N}^{2 / 3} \times {χ}^{1 / 6} \qquad ( 1 )$$

[in the expression, L0 represents a period of the structure body, a is a parameter indicating the size of the monomer, N represents a degree of polymerization, and χ is an interaction parameter, in which the value thereof is higher, the phase separation performance is higher]

Accordingly, the period (L0) of the structure body can be controlled by adjusting the composition and the total molecular weight of the block copolymer.

It has been known that the periodic structure formed by the block copolymer varies the form such as a cylinder (columnar phase), a lamella (plate phase), and a sphere (spherical phase) depending on a ratio of a volume of the polymer components, and the period depends on the molecular weight. Therefore, a method for increasing the molecular weight of the block copolymer has been considered in order to form a structure body of a relatively large period (L0) by utilizing the phase-separated structure formed by the self-organization of the block copolymer.

In addition, it has been also conceivable to use a method for using a block copolymer having a larger interaction parameter (c) than that of a block copolymer having a block of styrene and a block of methyl methacrylate, which is a general-purpose block copolymer.

For example, Japanese Unexamined Patent Application, First Publication No. 2022-020519 proposes a block copolymer in which a substituent is introduced into a part of a methyl methacrylate block.

### SUMMARY OF THE INVENTION

In order to form a fine pattern by utilizing the phase-separated structure formed by the self-organization of the block copolymer, the phase-separated structure formed by the block copolymer preferably has vertical orientation. In addition, in order to use the above-described fine pattern as an etching mask pattern, it is preferable to vertically orient the fine pattern with a relatively thick film thickness (for example, a film thickness of 25 nm or more).

However, in the block copolymer disclosed in Japanese Unexamined Patent Application, First Publication No. 2008-36491, when the film thickness increases, it is difficult to form a phase-separated structure having the vertical orientation.

The present invention has been made in consideration of the above circumstances, and an object of the present invention is to provide a resin composition for forming an etching mask pattern, which has excellent vertical orientation with a high film thickness, and a method for manufacturing an etching mask pattern using the same.

That is, a first aspect of the present invention is a resin composition for forming an etching mask pattern, the resin composition containing a block copolymer having a first block and a second block, and a homopolymer having a number-average molecular weight of less than 3,000, in which the first block is composed of a polymer consisting of a repeating structure of a constitutional unit represented by General Formula (b1), the second block is composed of a random copolymer consisting of a structure in which a constitutional unit represented by General Formula (b2m) and a constitutional unit represented by General Formula (b2g) are arranged in a disordered manner, the proportion of the volume of the first block to the total volume of the first block and the second block is 20% to 80% by volume, and the homopolymer includes a polymer consisting of a repeating structure of the constitutional unit represented by General Formula (b1).

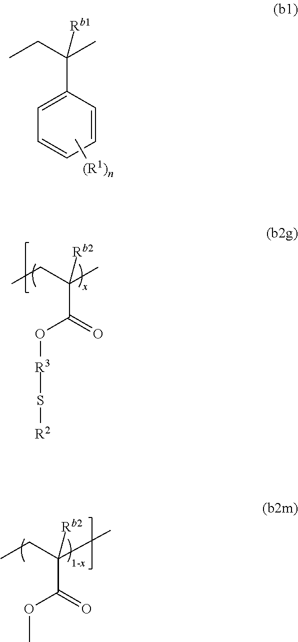

[in Formula (b1), R¹ is an alkyl group, R^{b1} is a hydrogen atom or a methyl group, n is an integer of 0 to 5, and in a case where n is an integer of 2 or more, a plurality of R¹'s may be the same or different from each other, in Formula (b2g), R² is an alkyl group which may have a silicon atom, a fluorine atom, a carboxy group, an amino group, a cyano group, a hydroxy group, or a phosphoric acid group, and R³ is a linear or branched alkylene group having 1 to 10 carbon atoms, which may have a hydroxy group, in Formulae (b2g) and (b2m), R^{b2} is a hydrogen atom, an alkyl group having 1 to 5 carbon atoms, or a halogenated alkyl group having 1 to 5 carbon atoms, and a plurality of R^{b2}'s may be the same or different from each other, and x represents a molar ratio and is more than 0 and less than 1]

A second aspect of the present invention is a method for manufacturing an etching mask pattern, the method including a step of applying the resin composition for forming an etching mask pattern according to the first aspect onto a support to form a layer containing a block copolymer, and a step of phase-separating the layer containing a block copolymer.

According to the present invention, it is possible to provide a resin composition for forming an etching mask pattern, which has excellent vertical orientation with a high film thickness, and a method for manufacturing an etching mask pattern using the same.

### BRIEF DESCRIPTION OF THE DRAWINGS

FIG. 1 is a schematic process diagram showing an exemplary embodiment of a method for manufacturing an etching mask pattern.

FIG. 2 is a diagram showing an exemplary embodiment of an optional step.

### DETAILED DESCRIPTION OF THE INVENTION

In the present specification and the scope of the present claims, the term “aliphatic” is a relative concept used with respect to “aromatic” and defines a group or compound that has no aromaticity.

A term “alkyl group” includes linear, branched, or cyclic monovalent saturated hydrocarbon groups unless otherwise specified. The same applies to an alkyl group in an alkoxy group.

A term “alkylene group” includes linear, branched, or cyclic divalent saturated hydrocarbon groups unless otherwise specified.

A “halogenated alkyl group” is a group in which a part of or all of hydrogen atoms in an alkyl group are substituted with halogen atoms. As the halogen atom, a fluorine atom, a chlorine atom, a bromine atom, and an iodine atom are exemplary examples.

The “fluorinated alkyl group” or a “fluorinated alkylene group” is a group obtained by substituting part or all of hydrogen atoms of an alkyl group or an alkylene group with a fluorine atom.

A term “constitutional unit” indicates a monomer unit constituting a polymer compound (a resin, a polymer, or a copolymer).

An expression “may have a substituent” includes a case where a hydrogen atom (—H) is substituted with a monovalent group and a case where a methylene group (—CH₂—) is substituted with a divalent group.

A term “exposure” is used as a general concept for irradiation with radiation.

A term “α-position (carbon atom at α-position)” means a carbon atom to which a side chain of a block copolymer is bonded, unless otherwise specified. The “carbon atom at the α-position” of a methyl methacrylate unit means a carbon atom to which a carbonyl group of methacrylic acid is bonded. The “carbon atom at the α-position” of a styrene unit means a carbon atom to which a benzene ring is bonded.

A term “number-average molecular weight” (Mn) is a number-average molecular weight in terms of standard polystyrene measured by size-exclusion chromatography, unless otherwise specified. A term “mass-average molecular weight” (Mw) is a mass-average molecular weight in terms of standard polystyrene measured by size-exclusion chromatography, unless otherwise specified. A value obtained by adding a unit (g·mol⁻) to the value of Mn or Mw represents a molar mass.

In the detailed description and claims of the present invention, in the specification and claims of the present invention, some structures represented by a chemical formula have an asymmetric carbon, and there may be enantiomers and diastereomers. Those isomers are collectively represented by one formula. These isomers may be used alone or in the form of a mixture.

### Resin Composition for Forming Etching Mask Pattern

The resin composition for forming an etching mask pattern according to the present embodiment contains a block copolymer having a first block and a second block, and a homopolymer having a number-average molecular weight of less than 3,000. The first block is composed of a polymer consisting of a repeating structure of a constitutional unit represented by General Formula (b1). The second block is composed of a random copolymer consisting of a structure in which a constitutional unit represented by General Formula (b2m) and a constitutional unit represented by General Formula (b2g) are arranged in a disordered manner. The proportion of the volume of the first block to the total volume of the first block and the second block is 20% to 80% by volume. The homopolymer includes a polymer consisting of a repeating structure of the constitutional unit represented by General Formula (b1).

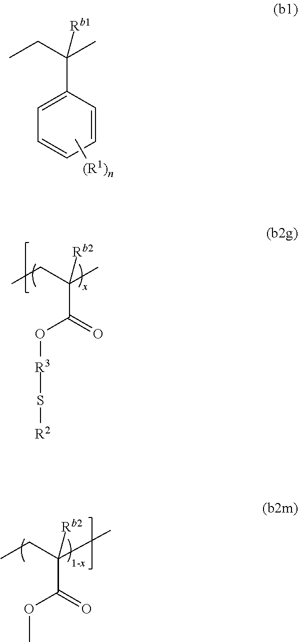

[in Formula (b1), R¹ is an alkyl group, R^{b1} is a hydrogen atom or a methyl group, n is an integer of 0 to 5, and in a case where n is an integer of 2 or more, a plurality of R¹'s may be the same or different from each other,
in Formula (b2g), R² is an alkyl group which may have a silicon atom, a fluorine atom, a carboxy group, an amino group, a cyano group, a hydroxy group, or a phosphoric acid group, and R³ is a linear or branched alkylene group having 1 to 10 carbon atoms, which may have a hydroxy group,
in Formulae (b2g) and (b2m), R^{b2} is a hydrogen atom, an alkyl group having 1 to 5 carbon atoms, or a halogenated alkyl group having 1 to 5 carbon atoms, and a plurality of R^{b2}'s may be the same or different from each other, and x represents a molar ratio and is more than 0 and less than 1]

### Block Copolymer: Component (BCP)

The block copolymer is a polymer in which a plurality of types of blocks (partial structural components in which constitutional units of the same type are repeatedly bonded) are bonded. The blocks constituting the block copolymer may be two types or may be three or more types.

The block copolymer (hereinafter, also referred to as “component (BCP)”) in the present embodiment has a first block and a second block.

### First Block

The first block is composed of a polymer consisting of a repeating structure of a constitutional unit represented by General Formula (b1) (hereinafter, also referred to as a

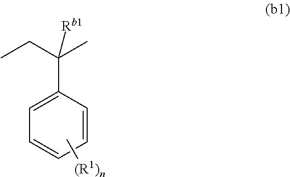

[in the formula, R¹ is an alkyl group, R^{b1} is a hydrogen atom or a methyl group, n is an integer of 0 to 5, and in a case where n is an integer of 2 or more, a plurality of R¹'s may be the same or different from each other]

In Formula (b1), R¹ is an alkyl group. The number of carbon atoms in the above-described alkyl group is preferably 1 to 5, more preferably 1 to 4, and still more preferably 1 to 3, and the above-described alkyl group is even more preferably an ethyl group or a methyl group. R¹ is particularly preferably a methyl group.

In Formula (b1), R^{b1} is a hydrogen atom or a methyl group.

In Formula (b1), n is preferably 0 to 3, more preferably 0 to 2, and still more preferably 0 or 1.

### Second Block

The second block is composed of a random copolymer consisting of a structure in which a constitutional unit represented by General Formula (b2m) (hereinafter, also referred to as a constitutional unit (b2m)) and a constitutional unit represented by General Formula (b2g) (hereinafter, also referred to as a constitutional unit (b2g)) are arranged in a disordered manner.

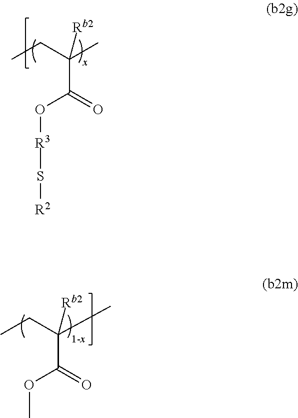

[in Formula (b2g), R² is an alkyl group which may have a silicon atom, a fluorine atom, a carboxy group, an amino group, a cyano group, a hydroxy group, or a phosphoric acid group, and R³ is a linear or branched alkylene group having 1 to 10 carbon atoms, which may have a hydroxy group,
in Formulae (b2g) and (b2m), R^{b2} is a hydrogen atom, an alkyl group having 1 to 5 carbon atoms, or a halogenated alkyl group having 1 to 5 carbon atoms, and a plurality of R^{b2}'s may be the same or different from each other, and x represents a molar ratio and is more than 0 and less than 1]
   Constitutional Unit (b2m)

The constitutional unit (b2m) is a constitutional unit represented by General Formula (b2m).

In Formula (b2m), R^{b2} is a hydrogen atom, an alkyl group having 1 to 5 carbon atoms, or a halogenated alkyl group having 1 to 5 carbon atoms. As the alkyl group having 1 to 5 carbon atoms as R^{b2}, a linear or branched alkyl group having 1 to 5 carbon atoms is preferable, and specifically, a methyl group, an ethyl group, a propyl group, an isopropyl group, an n-butyl group, an isobutyl group, a tert-butyl group, a pentyl group, an isopentyl group, a neopentyl group, and the like are exemplary examples. The halogenated alkyl group having 1 to 5 carbon atoms is a group in which a part of or all hydrogen atoms in the alkyl group having 1 to 5 carbon atoms are substituted with halogen atoms. The halogen atom is particularly preferably a fluorine atom.

R^{b2} is preferably a hydrogen atom, an alkyl group having 1 to 5 carbon atoms, or a fluorinated alkyl group having 1 to 5 carbon atoms; and from the viewpoint of industrial availability, more preferably a hydrogen atom or a methyl group and still more preferably a methyl group.

Constitutional Unit (b2g)

The constitutional unit (b2g) is a constitutional unit represented by General Formula (b2g).

In Formula (b2g), R^{b2} is a hydrogen atom, an alkyl group having 1 to 5 carbon atoms, or a halogenated alkyl group having 1 to 5 carbon atoms. The R^{b2} is the same as R^{b2} in Formula (b2m) described above.

In Formula (b2g), R² is an alkyl group which may have a silicon atom, a fluorine atom, a carboxy group, an amino group, a cyano group, a hydroxy group, or a phosphoric acid group. The above-described alkyl group may be linear or branched, or may include a ring structure. The above-described alkyl group is preferably a linear, branched, or cyclic alkyl group, and more preferably a linear or cyclic alkyl group. In a case where the above-described alkyl group is linear, it is sufficient that the number of carbon atoms therein is 1 or more, preferably 2 or more. The upper limit of the number of carbon atoms in the above-described linear alkyl group is not particularly limited, but from the viewpoint of phase separation performance, it is preferably 15 or less, more preferably 10 or less, still more preferably 8 or less, and even more preferably 6 or less. In a case where the above-described alkyl group is branched, it is sufficient that the number of carbon atoms therein is 3 or more. The upper limit of the number of carbon atoms in the above-described branched alkyl group is not particularly limited, but from the viewpoint of phase separation performance, it is preferably 15 or less, more preferably 10 or less, still more preferably 8 or less, and even more preferably 6 or less.

In a case where the above-described alkyl group has a ring structure, R² may be a cycloalkyl group, may be a group in which a cycloalkylene group is interposed in the middle of a linear or branched alkyl group, or may be a group in which a cycloalkyl group is bonded to a terminal of a linear or branched alkylene group. The above-described cycloalkyl group and cycloalkylene group may be a monocyclic group or a polycyclic group, but are preferably a monocyclic group. In a case where the above-described cycloalkyl group or the above-described cycloalkylene group is a monocyclic group, the number of ring members is preferably 3 to 8, more preferably 3 to 6, and still more preferably 5 or 6. In a case where the above-described alkyl group includes a ring structure, it is sufficient that R² has 3 or more carbon atoms. The upper limit of the number of carbon atoms in the above-described alkyl group including a ring structure is not particularly limited, but from the viewpoint of phase separation performance, it is preferably 15 or less, more preferably 10 or less, still more preferably 8 or less, and even more preferably 6 or less.

The number of carbon atoms in the alkyl group as R² is preferably 2 to 15, more preferably 2 to 10, still more preferably 2 to 8, and even more preferably 2 to 6.

The alkyl group as R² is preferably a linear alkyl group or cycloalkyl group having 2 to 6 carbon atoms.

The alkyl group as R² may have a silicon atom, a fluorine atom, a carboxy group, an amino group, a cyano group, a hydroxy group, or a phosphoric acid group. In a case where the alkyl group as R² has a fluorine atom, a carboxy group, an amino group, a cyano group, a hydroxy group, or a phosphoric acid group, the fluorine atom, carboxy group, amino group, cyano group, hydroxy group, or phosphoric acid group may be a substituent which substitutes a hydrogen atom of the alkyl group. The number of hydrogen atoms substituted in the above-described group is not particularly limited, but is preferably 1 to 3.

In a case where the alkyl group of R² has a silicon atom, the silicon atom may be a substituent which substitutes a methylene group (—CH₂—) in the alkyl group. The number of methylene groups substituted with the silicon atom is not particularly limited, but is preferably 1.

R² is preferably an alkyl group which may be substituted with an alkylsilyl group, a fluoromethyl group, a carboxy group, an amino group, a hydroxy group, a cyano group, or a phosphoric acid group. The alkyl group in the above-described alkylsilyl group preferably has 1 to 3 carbon atoms and more preferably has 1 or 2 carbon atoms. The above-described alkylsilyl group is preferably a trialkylsilyl group, more preferably a triethylsilyl group or a trimethylsilyl group, and still more preferably a trimethylsilyl group. The above-described fluoromethyl group is preferably a trifluoromethyl group.

Preferred examples of R² are shown below, but it is not limited thereto. In the formulae, * is a bonding site bonding to a sulfur atom(S) in Formula (b2g).

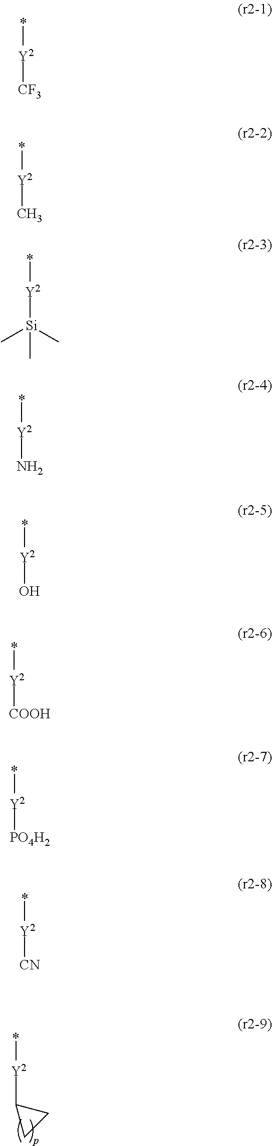

[in the formulae, Y2 is a single bond or a linear or branched alkylene group having 1 to 15 carbon atoms, and p is an integer of 1 to 10]

In Formulae (r2-1) to (r2-7), Y2 is a single bond or a linear or branched alkylene group having 1 to 15 carbon atoms. In a case where the above-described alkylene group is linear, the number of carbon atoms in the linear alkylene group is more preferably 1 to 10, still more preferably 1 to 8, and particularly preferably 1 to 5. In a case where the above-described alkylene group is branched, the number of carbon atoms in the branched alkylene group is more preferably 2 to 10, still more preferably 2 to 8, and particularly preferably 2 to 6.

The alkylene group as Y2 is preferably a linear alkylene group having 1 to 5 carbon atoms or a branched alkylene group having 2 to 6 carbon atoms.

In a case where R² is a group represented by any one of Formulae (r2-1) to (r2-8), Y2 is preferably a linear or branched alkylene group having 1 to 15 carbon atoms, and more preferably a linear alkylene group having 1 to 5 carbon atoms or a branched alkylene group having 2 to 6 carbon atoms. In a case where R² is a group represented by Formula (r2-9), Y2 is preferably a single bond or a linear alkylene group having 1 to 5 carbon atoms, and more preferably a single bond.

In General Formula (r2-9), p is preferably an integer of 1 to 6, more preferably an integer of 1 to 4, and still more preferably 3 or 4.

Specific examples of R² are shown below, but it is not limited thereto. In the formulae, * is a bonding site bonding to a sulfur atom(S) in Formula (b2g).

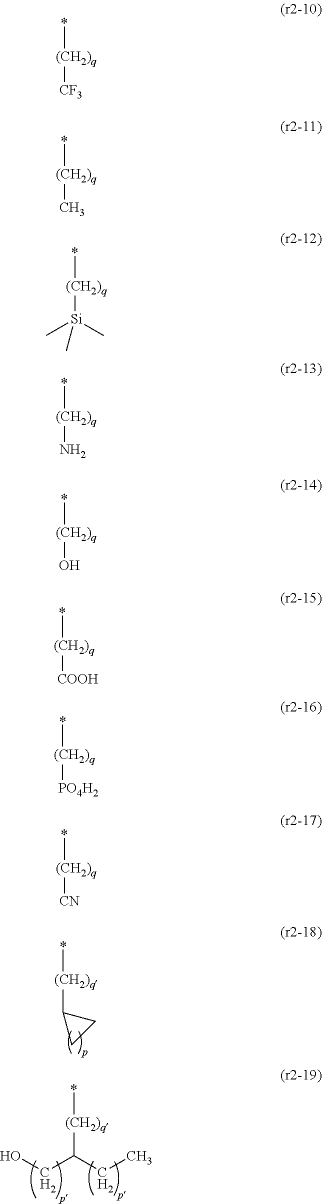

[in the formulae, q is an integer of 1 to 15, q′ is an integer of 0 to 15, p is an integer of 1 to 10, and q′ is each independently an integer of 0 to 10]

In the formulae, q is preferably 1 to 10, more preferably 1 to 8, still more preferably 1 to 6, and particularly preferably 1 to 5.

In Formulae (r2-18) and (r2-19), q′ is preferably 0 to 10, more preferably 0 to 8, still more preferably 0 to 6, and particularly preferably 0 to 5.

In Formula (r2-18), p is preferably an integer of 1 to 6, more preferably an integer of 1 to 4, and still more preferably 3 or 4.

In Formula (r2-19), p′ is preferably an integer of 1 to 8, more preferably an integer of 1 to 6, still more preferably an integer of 1 to 3, and particularly preferably 1 or 2.

In Formula (b2g), R³ is a linear or branched alkylene group having 1 to 10 carbon atoms, which may have a hydroxy group. In a case where the above-described alkylene group is linear, it is sufficient that the number of carbon atoms therein is 1 or more, preferably 3 or more. From the viewpoint of phase separation performance, the upper limit of the number of carbon atoms in the above-described linear alkylene group is preferably 8 or less, more preferably 5 or less, and still more preferably 4 or less. The number of carbon atoms in the above-described linear alkylene group is particularly preferably 3. In a case where the above-described alkylene group is branched, it is sufficient that the number of carbon atoms therein is 3 or more, preferably 4 or more. From the viewpoint of phase separation performance, the upper limit of the number of carbon atoms in the above-described branched alkylene group is preferably 8 or less, and more preferably 5 or less. The number of carbon atoms in the above-described alkylene group is preferably 3 to 10, more preferably 3 to 8, still more preferably 3 to 5, even more preferably 3 or 4, and particularly preferably 3.

The alkylene group as R³ is preferably a linear alkylene group having 3 carbon atoms.

The alkylene group as R³ may have a hydroxy group. The above-described hydroxy group may be a substituent which substitutes a hydrogen atom of the alkylene group. The number of hydrogen atoms substituted by the hydroxy group is not particularly limited, but is preferably 1 to 3, more preferably 1 or 2, and still more preferably 1.

The constitutional unit (b2g) is preferably a constitutional unit represented by General Formula (b2g-1).

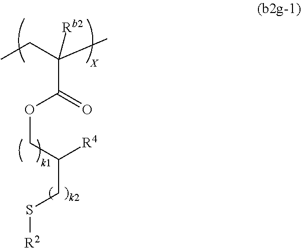

[in the formula, R⁴ is a hydrogen atom or a hydroxy group, k1 and k2 are each independently an integer of 1 to 5, and R^{b2} and R² are the same as R^{b2} and R² in Formula (b2g) described above]

In Formula (b2g-1), R^{b2} and R² are the same as R^{b2} and R² in Formula (b2g) described above. R² is preferably represented by Formulae (r2-1) to (r2-9) and more preferably represented by Formulae (r2-10) to (r2-19).

In Formula (b2g-1), R⁴ is a hydrogen atom or a hydroxy group.

In Formula (b2g-1), k1 and k2 are each independently an integer of 1 to 5. k1 and k2 are preferably 1 to 3, more preferably 1 or 2, and still more preferably 1.

Specific examples of the constitutional unit (b2g) are shown below, but it is not limited thereto. In the formulae. R represents a methyl group or a hydrogen atom, and a methyl group is preferable.

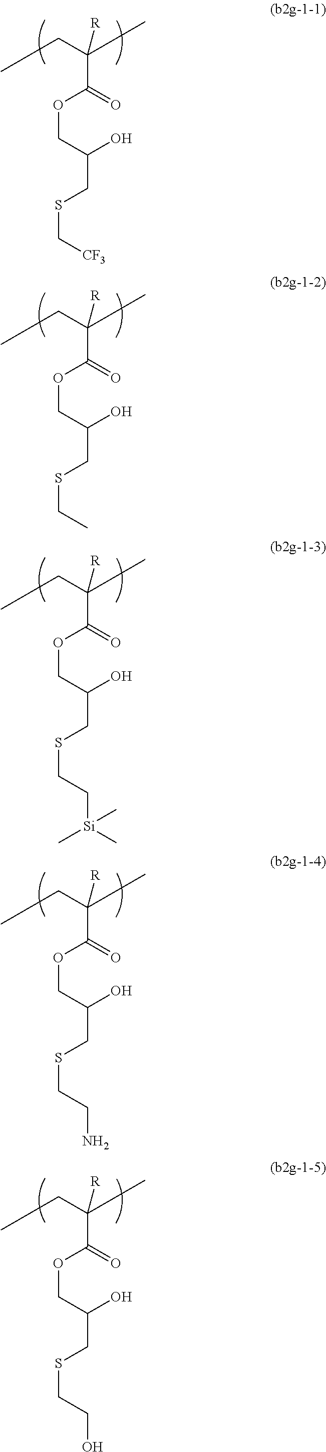

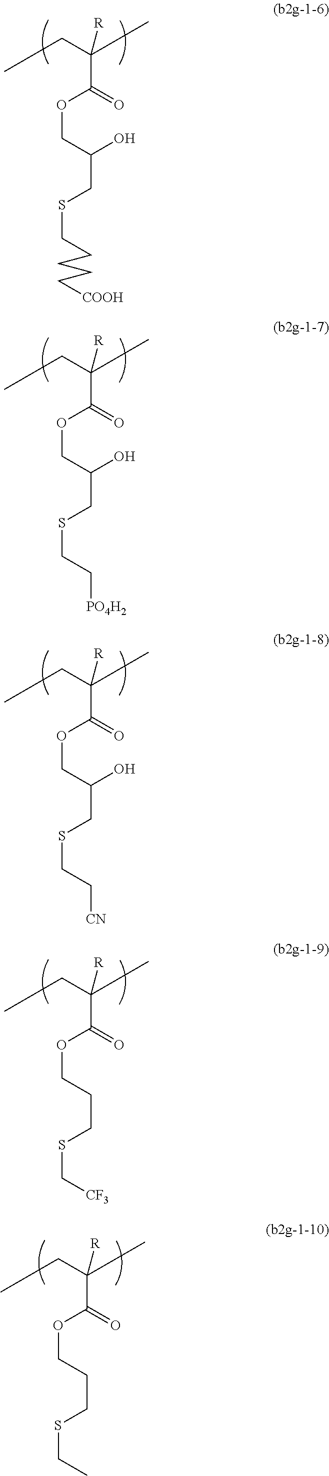

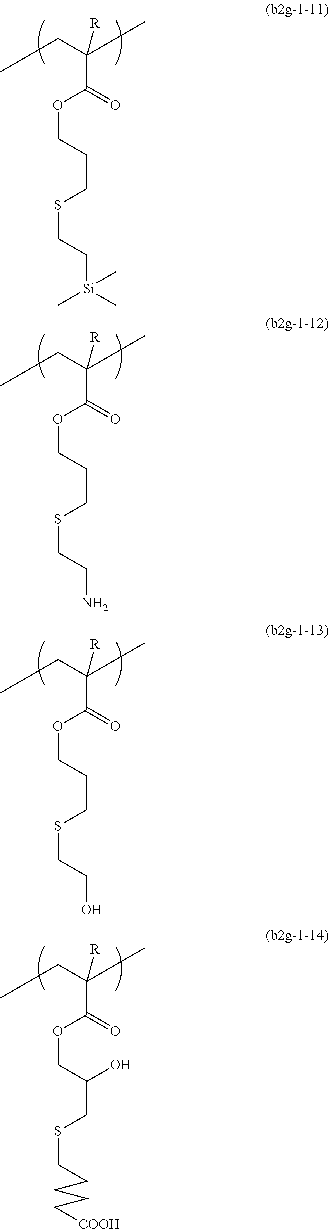

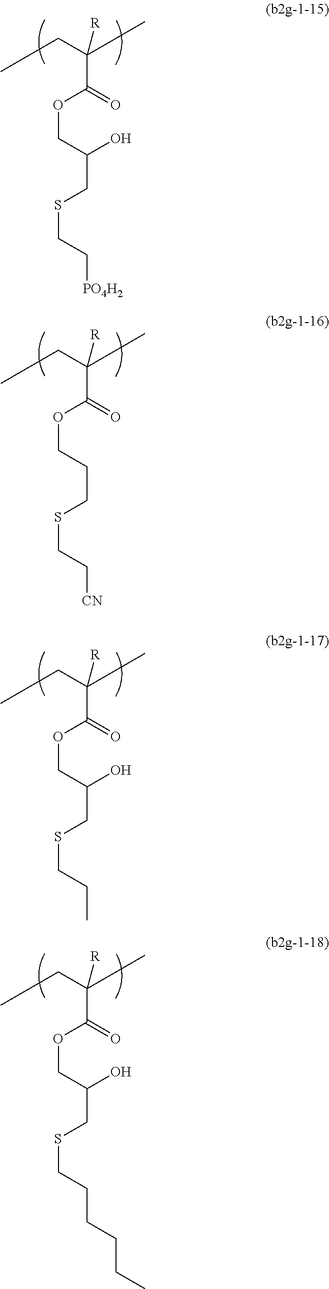

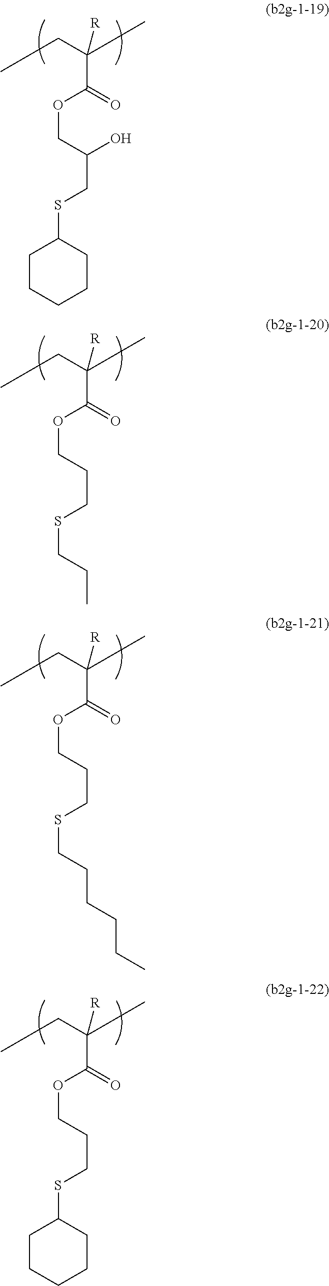

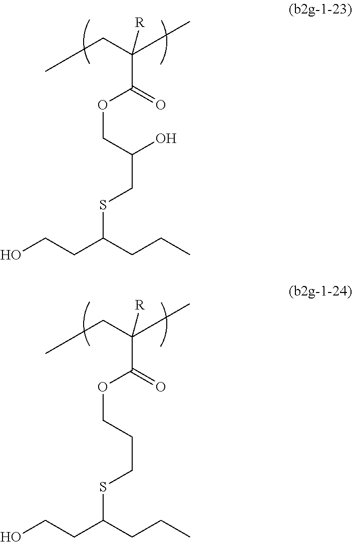

The second block is composed of a random copolymer consisting of a structure in which the above-described constitutional unit (b2g) and the above-described constitutional unit (b2m) are arranged in a disordered manner. In Formulae (b2g) and (b2m), x and 1-x represent a molar ratio of the constitutional unit (b2g) and the constitutional unit (b2m). x is more than 0 and less than 1. x can be appropriately determined depending on the type of the desired phase-separated structure. In a case of forming a phase-separated structure having a lamellar structure, x is preferably 0.01 to 0.3, and more preferably 0.1 to 0.3. In a case of forming a phase-separated structure having a cylinder structure, x is preferably 0.01 to 0.1, and more preferably 0.01 or more and less than 0.1.

In the component (BCP), the proportion of the volume of the first block to the total volume of the first block and the second block is 20% to 80% by volume. The proportion of the volume of the first block can be appropriately determined according to the type of the desired phase-separated structure. In a case of forming a phase-separated structure having a lamellar structure, the above-described proportion of the volume of the first block is preferably 35% to 65% by volume. In a case of forming a phase-separated structure having a cylinder structure, the above-described proportion of the volume of the first block is preferably 20% to 35% by volume or 65% to 80% by volume.

The proportion of the volume of the first block to the total volume of the first block and the second block in the component (BCP) can be obtained as follows.

From an analysis result of ¹H NMR, mol % of each of the first block and the second block in the component (BCP) is calculated, and % by mass of each block is calculated from a molecular weight of each block. The % by mass of each block is divided by a density of each block to calculate a ratio of volume of each block, and % by volume of the first block in the component (BCP) is calculated from the ratio of volume. The density of each block can be estimated by the atomic group contribution method (Fedors, R. F. Polym. Eng. Sci. 1974, 14, pp. 147 to 154). In a case where the first block is a polystyrene block (PS), 1.05 g·m⁻³ can be used as a density of PS. In a case where the second block is a polystyrene block (PS), 1.05 g·m⁻³ can be used as a density of PS. In a case where the second block has a constitutional unit induced from methyl methacrylate, 1.18 g·cm⁻³ can be used as a density of a structure constituting the constitutional unit. In a case where the second block has a constitutional unit induced from 2-hydroxy-3-(2,2,2-trifluoroethylsulfanyl) propyl methacrylate, 1.43 g·cm⁻³ can be used as a density of a structure constituting the constitutional unit. As for the density of each block, densities described in documents (Polymer Handbook, 4th ed.; Wiley: New York, 2004) and the like can also be used.

The component (BCP) may have other blocks in addition to the first block and the second block. As a preferred aspect, the component (BCP) is a block copolymer composed of the first block and the second block.

A number-average molecular weight (Mn) (in terms of polystyrene according to size-exclusion chromatography) of the component (BCP) is not particularly limited, but is preferably 5,000 to 100,000, more preferably 6,000 to 7,000, still more preferably 8,000 to 40,000, and particularly preferably 10,000 to 40,000.

A polydispersity (Mw/Mn) of each block constituting the component (BCP) is preferably 1.0 to 1.5, more preferably 1.0 to 1.4, and still more preferably 1.0 to 1.3.

### Method for Producing Block Copolymer (Component (BCP))

The component (BCP) can be produced by, for example, a production method including the following steps.

Step (p1): step of obtaining a block copolymer having the first block and a precursor of the second block (hereinafter, also referred to as “BCP precursor”)

Step (p2): step of obtaining a block copolymer (component (BCP)) containing the first block and the second block by reacting the precursor of the second block in the BCP precursor with a compound represented by R²—SH (R² is the same as R² in Formula (b2g) described above)

### Step (p1):

The precursor of the second block is a random copolymer consisting of a structure in which a constitutional unit (b2gp) that is a precursor of the constitutional unit (b2g) and the constitutional unit (b2m) are arranged in a disordered manner. The constitutional unit (b2gp) is a constitutional unit including an epoxy group or a vinyl group, and a constitutional unit represented by General Formula (b2gp) is an exemplary example.

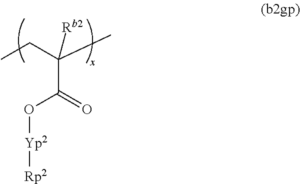

[in the formula, Rp² represents an epoxy group or a vinyl group, Yp² represents a linear or branched alkylene group having 1 to 8 carbon atoms, and R^{b2} is a hydrogen atom, an alkyl group having 1 to 5 carbon atoms, or a halogenated alkyl group having 1 to 5 carbon atoms]

The BCP precursor can be obtained by, for example, performing a polymerization reaction of a monomer for inducing the constitutional unit (b1) (for example, styrene or a derivative thereof; hereinafter, the monomer is also referred to as a monomer (b1)), and then performing the polymerization reaction by adding a monomer for inducing the constitutional unit (b2gp) (for example, glycidyl methacrylate, allyl methacrylate, and the like; hereinafter, the monomer is also referred to as a monomer (b2gp)) and a monomer for inducing the constitutional unit (b2m) (for example, methyl methacrylate; hereinafter, the monomer is also referred to as a monomer (b2m)) to the polymerization reaction solution. Alternatively, the BCP precursor can be obtained by performing a polymerization reaction with a mixture of the monomer (b2gp) and the monomer (b2m), and then performing the polymerization reaction by adding the monomer (b1) to the polymerization reaction solution. As the polymerization reaction, living polymerization is preferable because it is easy to synthesize with narrow dispersion. As a preferred living polymerization method, living anionic polymerization and living radical polymerization are exemplary examples, and living anionic polymerization is particularly preferable because the narrow dispersion can be further achieved.

### Step (p2):

The compound represented by R²—SH (hereinafter, also referred to as “compound (R²—SH)”) is a compound obtained by a reaction of an epoxy group or a vinyl group of the constitutional unit (b2gp) to convert the constitutional unit (b2gp) into the constitutional unit (b2g).

In a case where the constitutional unit (b2gp) includes an epoxy group, the reaction between the BCP precursor and the compound (R²—SH) can be performed in an organic solvent such as tetrahydrofuran in the presence of a catalyst such as lithium hydroxide. As a reaction temperature, for example, 20° C. to 60° C. are exemplary examples, and 30° C. to 50° C. are preferable and 35° C. to 45° C. are more preferable. A reaction time can be appropriately set according to the amount of the BCP precursor used, and may be sufficient to convert all the constitutional units (b2gp) in the precursor of the second block into the constitutional units (b2g). As a reaction time, for example, 1 to 10 hours are exemplary examples. In a case where the constitutional unit (b2gp) includes a vinyl group, the reaction between the BCP precursor and the compound (R²—SH) can be performed by a thiol-ene reaction. The thiol-ene reaction can be carried out in an organic solvent such as tetrahydrofuran in the presence of a catalyst such as azobisisobutyronitrile (AIBN). As a reaction temperature, for example, 60° C. to 90° C. are exemplary examples, and 70° C. to 90° C. are preferable and 75° C. to 85° C. are more preferable. A reaction time can be appropriately set according to the amount of the BCP precursor used, and may be sufficient to convert all the constitutional units (b2gp) in the precursor of the second block into the constitutional units (b2g). As a reaction time, for example, 1 to 10 hours are exemplary examples.

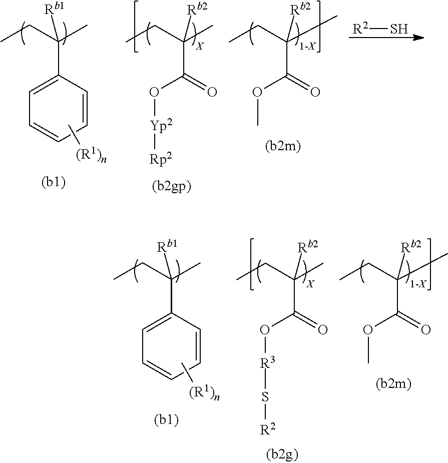

[in the formulae, R¹, R^{b1}, and n are each the same as R¹, R^{b1}, and n in Formula (b1) described above, R² and R³ are the same as R² and R³ in Formula (b2g) described above, R^{b2} and x are the same as R^{b2} and x in Formulae (b2g) and (b2m) described above, Yp² represents a linear or branched alkyl group having 1 to 8 carbon atoms, and Rp² represents an epoxy group or a vinyl group]

### Homopolymer: Component (H)

The homopolymer is a homopolymer having a number-average molecular weight of less than 3,000 (hereinafter, also referred to as “component (H)”). The component (H) includes a polymer consisting of a repeating structure of the constitutional unit (b1) represented by General Formula (b1) described above.

### Polymer Consisting of Repeating Structure of Constitutional Unit (b1): Component (H1)

The component (H) includes a polymer consisting of a repeating structure of the constitutional unit (b1) (hereinafter, also referred to as “component (H1)”). The description of the constitutional unit (b1) included in the component (H1) is the same as the description of the constitutional unit (b1) included in the first block of the component (BCP) above.

The constitutional unit (b1) included in the component (H1) may be the same or different from the constitutional unit (b1) included in the first block of the component (BCP), but is preferably the same. For example, in a case where the first block of the component (BCP) is a polystyrene block, the component (H1) is preferably polystyrene.

It is sufficient that the number-average molecular weight (Mn) (in terms of polystyrene according to size-exclusion chromatography) of the component (H1) is less than 3,000. In a case where the Mn of the component (H1) is less than 3,000, the component (H1) is easily uniformly dispersed in the layer containing a block copolymer, and vertical orientation with a high film thickness (for example, a film thickness of 25 nm or more) is improved. As the upper limit of Mn of the component (H1), for example, 2,900 or less, 2,800 or less, 2,700 or less, 2,600 or less, 2,500 or less, 2,400 or less, 2,300 or less, 2,200 or less, 2,100 or less, and 2,000 or less are exemplary examples. As the lower limit of Mn of the component (H1), for example, 1,000 or more and 1,200 or more are exemplary examples. As the range of Mn of the component (H1), for example, 1,000 to 2,900 are exemplary examples, and 1,000 to 2,500 is preferable and 1,200 to 2,000 is more preferable.

In a case where the Mn of the component (H1) is within the above-described preferred range, a phase-separated structure having excellent vertical orientation is easily formed.

As the amount of the component (H1) in the resin composition for forming an etching mask pattern according to the present embodiment, with respect to 100 parts by mass of the component (BCP), 1 part by mass or more is an exemplary example, and 5 parts by mass or more is preferable, 10 parts by mass or more is more preferable, and 15 parts by mass or more is still more preferable. As the upper limit of the amount of the component (H1), with respect to 100 parts by mass of the component (BCP), 100 parts by mass or less is an exemplary example, and 70 parts by mass or less is preferable, 50 parts by mass or less is more preferable, and 30 parts by mass or less is still more preferable. As the range of the amount of the component (H1), with respect to 100 parts by mass of the component (BCP), 1 to 100 parts by mass are exemplary examples, and 10 to 70 parts by mass are preferable, 15 to 50 parts by mass are more preferable, and 15 to 30 parts by mass are still more preferable.

In a case where the amount of the component (H1) is within the above-described preferred range, a phase-separated structure having excellent vertical orientation is easily formed.

One kind of the component (H1) may be used alone, or two or more kinds thereof may be used in combination.

In a case where the component (H) includes two or more kinds of the components (H1), the amount of the component (H1) means the total amount of the two or more kinds of the components (H1).

### Other Homopolymers

The component (H) may include other homopolymers in addition to the component (H1). As the other homopolymers, a polymer consisting of a repeating structure of the constitutional unit (b2m) represented by General Formula (b2m) described above (hereinafter, also referred to as “component (H2)”) is an exemplary example.

Polymer Consisting of Repeating Structure of Constitutional Unit (b2m): Component (H2)

The description of the constitutional unit (b2m) included in the component (H2) is the same as the description of the constitutional unit (b2m) included in the second block of the component (BCP) above.

The constitutional unit (b2m) included in the component (H2) may be the same or different from the constitutional unit (b2m) included in the second block of the component (BCP), but is preferably the same. For example, in a case where the second block of the component (BCP) is a poly(methyl methacrylate) block, the component (H1) is preferably poly(methyl methacrylate).

It is sufficient that the number-average molecular weight (Mn) (in terms of polystyrene according to size-exclusion chromatography) of the component (H2) is less than 3,000. In a case where the Mn of the component (H2) is less than 3,000, the component (H2) is easily uniformly dispersed in the layer containing a block copolymer, and vertical orientation with a high film thickness (for example, a film thickness of 25 nm or more) is improved. As the upper limit of Mn of the component (H2), for example, 2,900 or less, 2,800 or less, 2,700 or less, 2,600 or less, 2,500 or less, 2,400 or less, 2,300 or less, 2,200 or less, 2,100 or less, and 2,000 or less are exemplary examples. As the lower limit of Mn of the component (H2), for example, 1,000 or more and 1,200 or more are exemplary examples. As the range of Mn of the component (H2), for example, 1,000 to 2,900 are exemplary examples, and 1,000 to 2,500 is preferable and 1,200 to 2,000 is more preferable.

In a case where the Mn of the component (H2) is within the above-described preferred range, a phase-separated structure having excellent vertical orientation is easily formed.

In a case where the component (H) includes the component (H2), as the amount of the component (H2) in the resin composition for forming an etching mask pattern according to the present embodiment, with respect to 100 parts by mass of the component (BCP), 90 parts by mass or less is an exemplary example, and 70 parts by mass or less is preferable, 50 parts by mass or less is more preferable, and 30 parts by mass or less is still more preferable. In a case where the component (H) includes the component (H2), the amount of the component (H2) may be 1 part by mass or more, 5 parts by mass or more, 10 parts by mass or more, or 15 parts by mass or more with respect to 100 parts by mass of the component (BCP). As the range of the amount of the component (H2), with respect to 100 parts by mass of the component (BCP), 0 to 90 parts by mass are exemplary examples, and 0 to 70 parts by mass are preferable, 0 to 50 parts by mass are more preferable, 0 to 30 parts by mass are still more preferable, and 0 to 25 parts by mass are even more preferable.

In a case where the amount of the component (H2) is within the above-described preferred range, a phase-separated structure having excellent vertical orientation is easily formed.

One kind of the component (H2) may be used alone, or two or more kinds thereof may be used in combination.

In a case where the component (H) includes two or more kinds of the components (H2), the amount of the component (H2) means the total amount of the two or more kinds of the components (H2).

In a case where the component (H) includes the component (H2), the amount of the component (H2) is preferably 100 parts by mass or less with respect to 100 parts by mass of the component (H1). The amount of the component (H2) may be 90 parts by mass or less, 80 parts by mass or less, 70 parts by mass or less, 60 parts by mass or less, 50 parts by mass or less, or 40 parts by mass or less with respect to 100 parts by mass of the component (H1).

An amount of the component (H) in the resin composition for forming an etching mask pattern according to the present embodiment is preferably 100 parts by mass or less with respect to 100 parts by mass of the component (BCP). In a case where the component (H) includes two or more kinds of the homopolymers, the amount of the component (H) means the total amount of the two or more kinds of the homopolymers. As the amount of the component (H), with respect to 100 parts by mass of the component (BCP), 5 parts by mass or more is an exemplary example, and 10 parts by mass or more is preferable, 20 parts by mass or more is more preferable, and 30 parts by mass or more is still more preferable. As the upper limit of the amount of the component (H), with respect to 100 parts by mass of the component (BCP), 100 parts by mass or less is an exemplary example, and 70 parts by mass or less is preferable, 60 parts by mass or less is more preferable, and 50 parts by mass or less is still more preferable. As the range of the amount of the component (H), with respect to 100 parts by mass of the component (BCP), 5 to 100 parts by mass are exemplary examples, and 10 to 70 parts by mass are preferable, 20 to 60 parts by mass are more preferable, and 30 to 50 parts by mass are still more preferable.

In a case where the amount of the component (H) is within the above-described preferred range, a phase-separated structure having excellent vertical orientation is easily formed.

The resin composition for forming an etching mask pattern according to the present embodiment may or may not contain a homopolymer having an Mn of 3,000 or more, but it is preferable that the resin composition does not contain this homopolymer. By not containing the homopolymer having an Mn of 3,000 or more in the resin composition for forming an etching mask pattern according to the present embodiment, a phase-separated structure having excellent vertical orientation is more easily formed.

### Organic Solvent Component

The resin composition for forming an etching mask pattern according to the present embodiment can be prepared by dissolving the above-described component (BCP) and the above-described component (H) in an organic solvent component.

Any organic solvent component may be used as long as it can dissolve each component to be used and form a homogeneous solution, and arbitrary solvents may be selected from any solvents known in the related art as a solvent for a film composition containing a resin as a main component.

As the organic solvent component, for example, lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond such as ethylene glycol monoacetate, diethylene glycol monoacetate, propylene glycol monoacetate, or dipropylene glycol monoacetate; polyhydric alcohol derivatives such as compounds having an ether bond, for example, a monoalkylether such as monomethylether, monocthylether, monopropylether, or monobutylether or monophenylether of any of the polyhydric alcohols or the compounds having an ester bond [among these, propylene glycol monomethyl ether acetate (PGMEA), or propylene glycol monomethyl ether (PGME) is preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenctole, butylphenylether, ethylbenzene, diethylbenzene, pentylbenzene, isopropylbenzene, toluene, xylene, cymene, and mesitylene; and the like are exemplary examples.

The organic solvent component may be used alone or as a mixed solvent of two or more kinds thereof. Among these, propylene glycol monomethyl ether acetate (PGMEA), propylene glycol monomethyl ether (PGME), cyclohexanone, or EL is preferable.

In addition, a mixed solvent obtained by mixing PGMEA with a polar solvent is also preferable. A blending ratio (mass ratio) of the mixed solvent can be appropriately determined in consideration of compatibility between PGMEA and the polar solvent, and it is preferably in a range of 1:9 to 9:1 and more preferably in a range of 2:8 to 8:2.

For example, in a case where EL is blended as the polar solvent, a mass ratio of PGMEA:EL is preferably 1:9 to 9:1 and more preferably 2:8 to 8:2. In addition, in a case where PGME is blended as the polar solvent, a mass ratio of PGMEA:PGME is preferably 1:9 to 9:1, more preferably 2:8 to 8:2, and still more preferably 3:7 to 7:3. In addition, in a case where PGME and cyclohexanone are blended as the polar solvent, a mass ratio of PGMEA:(PGME+cyclohexanone) is preferably 1:9 to 9:1, more preferably 2:8 to 8:2, and still more preferably 3:7 to 7:3.

In addition, as the organic solvent component in the resin composition for forming an etching mask pattern, in addition to those solvents, a mixed solvent in which PGMEA, EL, or the above-described mixed solvent of PGMEA and a polar solvent is mixed with γ-butyrolactone is also preferable. In this case, as a mixing proportion, a mass ratio of the former and the latter is preferably set to 70:30 to 95:5.

The concentration of the organic solvent component contained in the resin composition for forming an etching mask pattern is not particularly limited, and the component is appropriately set at a concentration with which the coating can be performed according to the coating film thickness. A concentration of solid contents is generally used in a range of 0.2% to 70% by mass, preferably in a range of 0.2% to 50% by mass.

### Optional Component

In addition to the above-described component (BCP), component (H), and organic solvent component, the resin composition for forming an etching mask pattern may further contain, as desired, a miscible additive such as an additional resin for improving the performance of the layer, a surfactant for improving coatability, a dissolution inhibitor, a plasticizer, a stabilizer, a colorant, a halation inhibitor, a dye, a sensitizer, a base promoter, and a basic compound.

In the resin composition for forming an etching mask pattern according to the present embodiment described above, since the resin composition contains the component (H) in addition to the component (BCP), a phase-separated structure having favorable vertical orientation even with a high film thickness (for example, a film thickness of 25 nm or more) can be formed. Therefore, a phase-separated structure with a high film thickness (for example, a film thickness of 25 nm or more, preferably 30 nm or more) can be formed in a vertically oriented manner, and the phase-separated structure can be used as an etching mask pattern.

In a case where the second block has the constitutional unit (b2g), the component (BCP) can increase the value of χ as compared with a block copolymer (PS-b-PMMA) having a block of styrene and a block of methyl methacrylate. As a result, it is possible to form a finer phase-separated structure having a shorter period by using the block copolymer having a lower degree of polymerization (N). However, in a case where the value of χ is high, the vertical orientation tends to decrease. In particular, at a film thickness (for example, a film thickness of 25 nm or more, and preferably 30 nm or more) applicable to the etching mask pattern, the component (BCP) is less likely to form a phase-separated structure vertically oriented.

Since the resin composition for forming an etching mask pattern according to the present embodiment contains the component (H) in addition to the component (BCP), the vertical orientation is improved, and a phase-separated structure vertically oriented at the film thickness applicable to the etching mask pattern can be formed.

### Method for Manufacturing Etching Mask Pattern

The method for manufacturing an etching mask pattern according to the present embodiment includes a step of applying the above-described resin composition for forming an etching mask pattern according to the embodiment onto a support to form a layer containing a block copolymer (hereinafter, referred to as “step (i)”), and a step of phase-separating the layer containing a block copolymer (hereinafter, referred to as “step (ii)”).

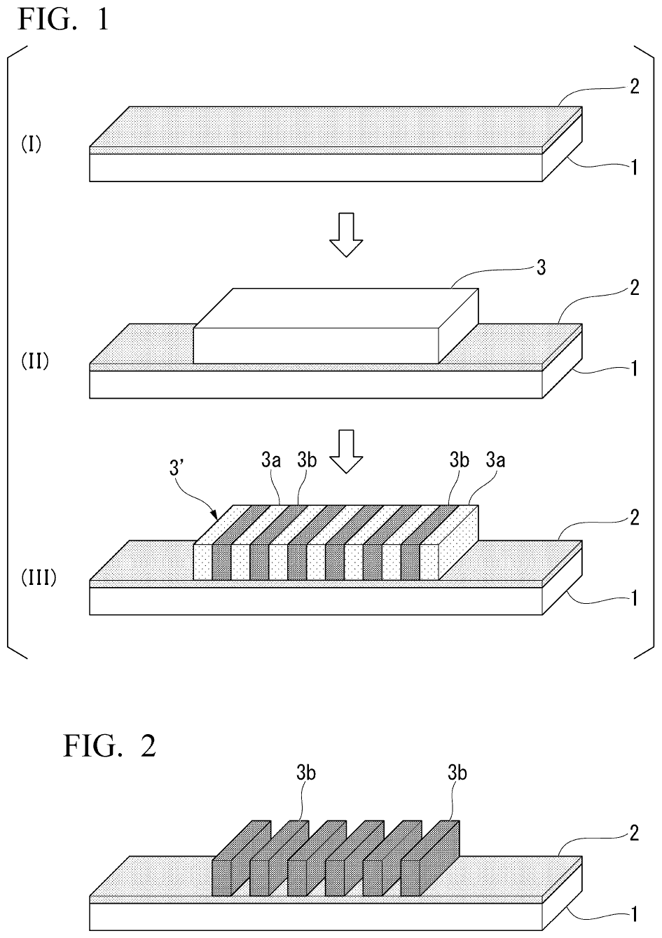

Hereinafter, the method for manufacturing an etching mask pattern will be specifically described with reference to FIG. 1. However, the present invention is not limited thereto.

FIG. 1 shows an exemplary embodiment of the method for manufacturing an etching mask pattern.

In the embodiment shown in FIG. 1, first, an undercoat agent layer 2 is formed by applying an undercoat agent onto a support 1 (FIG. 1(I)).

Next, the above-described resin composition for forming an etching mask pattern according to the embodiment is applied onto the undercoat agent layer 2 to form a layer (BCP layer) 3 containing a block copolymer (FIG. 1 (II); above, step (i)).

Next, the BCP layer 3 is phase-separated into a phase 3a and a phase 3b by a heating and annealing treatment (FIG. 1 (III); step (ii)).

As a result, a structure body 3′ including a phase-separated structure is produced on the support 1 on which the undercoat agent layer 2 had been formed. The structure body 3′ including the phase-separated structure can be used for manufacturing an etching mask pattern.

### Step (i)

In the step (i), the support 1 is coated with the resin composition for forming an etching mask pattern to form the BCP layer 3.

In the embodiment shown in FIG. 1, first, the undercoat agent layer 2 is formed by applying the undercoat agent onto the support 1.

By providing the undercoat agent layer 2 on the support 1, a hydrophilic and hydrophobic balance between a surface of the support 1 and the layer 3 containing the block copolymer (BCP layer) can be achieved.

That is, in a case where the undercoat agent layer 2 contains a resin component having the constitutional unit (b1) constituting the above-described first block, adhesiveness between the phase of the BCP layer 3, formed of the first block, and the support 1 is enhanced. In a case where the undercoat agent layer 2 contains a resin component having the constitutional unit (b2) constituting the above-described second block, adhesiveness between the phase of the BCP layer 3, formed of the second block, and the support 1 is enhanced.

Accordingly, a phase-separated structure oriented in a direction perpendicular to the surface of the support 1 is likely to be formed due to the phase separation of the BCP layer 3.

### Undercoat Agent:

### A Resin Composition can be Used as the Undercoat Agent.

The resin composition for the undercoat agent can be appropriately selected from the resin compositions known in the related art, which are used for forming a thin film depending on the type of the blocks constituting the component (BCP).

The resin composition for the undercoat agent may be, for example, a thermopolymerizable resin composition or may be a photosensitive resin composition such as a positive-type resist composition or a negative-type resist composition. In addition, a non-polymerizable film formed by applying a compound as a surface treating agent may be used as the undercoat agent layer. For example, a siloxane-based organic monomolecular film formed by applying phenethyltrichlorosilane, octadecyltrichlorosilane, hexamethyldisilazane, or the like as a surface treating agent can also be suitably used as an undercoat agent layer.

As the resin composition, for example, a resin composition which contains a resin having both of the constitutional unit (b1) constituting the first block and the constitutional unit (b2m) constituting the second block, a resin composition which contains a resin having constitutional units having high affinity with each block constituting the component (BCP), and the like are exemplary examples.

As the resin composition for the undercoat agent, for example, a composition which contains a resin having both styrene and methyl methacrylate as constitutional units, or a compound or a composition, which includes both a site having high affinity with styrene, such as an aromatic ring, and a site having high affinity with methyl methacrylate (a highly polar functional group) is preferably used.

As the resin having both styrene and methyl methacrylate as constitutional units, a random copolymer of styrene and methyl methacrylate, an alternating polymer of styrene and methyl methacrylate (a polymer obtained by alternately copolymerizing each monomer), and a random copolymer of styrene, methyl methacrylate, and (hydroxyethyl) methacrylate are exemplary examples. From the viewpoint of forming a phase-separated structure vertically oriented to the BCP layer, the proportion of the styrene constitutional unit in the above-described resin is preferably 20 to 90 mol % and more preferably 30 to 85 mol % with respect to the total (100 mol %) of all constitutional units constituting the resin.

In addition, as the composition including both the site having high affinity with styrene and the site having high affinity with methyl methacrylate, for example, for example, a composition which contains a resin obtained by polymerizing at least, as monomers, a monomer having an aromatic ring and a monomer having a highly polar functional group is an exemplary example. As the monomer having an aromatic ring, a monomer having an aryl group obtained by removing a hydrogen atom from an aromatic hydrocarbon ring, such as a phenyl group, a biphenyl group, a fluorenyl group, a naphthyl group, an anthryl group, and a phenanthryl group, or having a heteroaryl group in which carbon atoms constituting the ring of these groups are partially substituted with a heteroatom such as an oxygen atom, a sulfur atom, and a nitrogen atom is an exemplary example. In addition, as the monomer having a highly polar functional group, a monomer having a trimethoxysilyl group, a trichlorosilyl group, an epoxy group, a glycidyl group, a carboxy group, a hydroxy group, a cyano group, a hydroxyalkyl group in which the hydrogen atoms of the alkyl group are partially substituted with a hydroxyl group, and the like is an exemplary example. From the viewpoint of forming a phase-separated structure vertically oriented to the BCP layer, the proportion of the constitutional unit induced from the monomer having an aromatic ring in the above-described resin is preferably 20 to 90 mol % and more preferably 30 to 85 mol % with respect to the total (100 mol %) of all constitutional units constituting the resin.

In addition, as the compound including both the site having high affinity with styrene and the site having high affinity with methyl methacrylate, a compound including both an aryl group such as phenethyltrichlorosilane and a highly polar functional group, a compound including both an alkyl group such as an alkylsilane compound and a highly polar functional group, and the like are exemplary examples.

The resin composition for the undercoat agent can be produced by dissolving the above-described resin in a solvent.

As such a solvent, any solvent may be used as long as it can dissolve each component to be used and form a homogeneous solution. For example, the same solvent as the organic solvent component exemplary described in the resin composition for forming an etching mask pattern according to the above-described embodiment is an exemplary example.

The type of the support 1 is not particularly limited as long as the resin composition can be applied onto its surface. For example, a substrate made of an inorganic material such as a metal (silicon, copper, chromium, iron, and aluminum), glass, titanium oxide, silica or mica; a substrate made of an oxide such as SiO₂; a substrate made of a nitride such as SiN; a substrate made of an oxynitride such as SiON; and a substrate made of an organic material such as acryl, polystyrene, cellulose, cellulose acetate, phenolic resin, and the like are exemplary examples. Among these, a metal substrate is suitable, and for example, a structure body having a cylinder structure is likely to be formed in a silicon substrate (Si substrate) or a copper substrate (Cu substrate). Among these, an Si substrate is particularly suitable.

The size and shape of the support 1 are not particularly limited. The support 1 is not necessarily required to have a smooth surface, and substrates of various shapes can be appropriately selected. For example, a substrate having a curved surface, a flat plate having a surface with an uneven shape, and a substrate with a flaky shape or the like are exemplary examples.

An inorganic and/or organic film may be provided on the surface of the support 1.

As the inorganic film, an inorganic antireflection film (inorganic BARC) is an exemplary example. As the organic film, an organic antireflection film (organic BARC) is an exemplary example.

The inorganic film can be formed, for example, by applying an inorganic antireflection film composition such as a silicon-based material onto a support and by sintering the film.

For example, the organic film can be formed by applying a material for forming an organic film, in which a resin component and the like constituting the film are dissolved in an organic solvent, onto a substrate using a spinner or the like, and baking the film under heating conditions at preferably 200° C. to 300° C. for preferably 30 to 300 seconds and more preferably 60 to 180 seconds. The material for forming an organic film does not necessarily need to have sensitivity to light or electron beams, which is essential for a resist film, and may have sensitivity or does not have to have sensitivity. Specifically, a resist or a resin generally used for the production of semiconductor elements or liquid crystal display elements can be used.

In addition, it is preferable that the material for forming an organic film is a material capable of forming an organic film which can be subjected to etching, particularly dry etching, so that the organic film can be etched by using a pattern formed from a block copolymer, which is formed by processing the BCP layer 3, to transfer the pattern onto the organic film, and an organic film pattern can be formed. Above all, the material for forming an organic film is preferably a material capable of forming an organic film capable of being subjected to etching such as oxygen plasma etching. Such a material for forming an organic film may be a material conventionally used for forming an organic film such as organic BARC. For example, ARC series manufactured by Nissan Chemical Industries, Ltd., AR series manufactured by Rohm and Haas Company, SWK series manufactured by Tokyo Ohka Kogyo Co., Ltd., and the like are exemplary examples.

A method of forming the undercoat agent layer 2 by applying the undercoat agent onto the support 1 is not particularly limited, and the undercoat agent layer 2 can be formed by a known method in the related art.

For example, the undercoat agent layer 2 can be formed by applying the undercoat agent onto the support 1 by a known method in the related art, such as using a spin coating or a spinner, to form a coating film, and drying the coating film.

As a method of drying the coating film, any method of drying the coating film may be used as long as the solvent contained in the undercoat agent can be volatilized, and for example, a method of baking the coating film is an exemplary example. In this case, a baking temperature is preferably 80° C. to 300° C., more preferably 180° C. to 270° C., and still more preferably 220° C. to 250° C. The baking time is preferably 30 to 500 seconds and more preferably 60 to 400 seconds.

The thickness of the undercoat agent layer 2 after drying the coating film is preferably approximately 10 to 100 nm and more preferably approximately 40 to 90 nm.

The surface of the support 1 may be cleaned in advance before forming the undercoat agent layer 2 on the support 1. Coatability of the undercoat agent is improved by cleaning the surface of the support 1.

Regarding the cleaning treatment method, known methods in the related art can be utilized, and an oxygen plasma treatment, an ozone oxidation treatment, an acid alkali treatment, a chemical modification treatment, and the like are exemplary examples.

After the undercoat agent layer 2 is formed, the undercoat agent layer 2 may be rinsed as necessary using a rinse liquid such as a solvent. Since uncrosslinked portions and the like in the undercoat agent layer 2 are removed by this rinsing, the affinity with at least one block constituting the block copolymer is improved, and a phase-separated structure including a cylinder structure oriented in a direction perpendicular to the surface of the support 1 is likely to be formed.

The rinse liquid may be any one which can dissolve the uncrosslinked portions, and a solvent such as propylene glycol monomethyl ether acetate (PGMEA), propylene glycol monomethyl ether (PGME), and ethyl lactate (EL), a mixed solvent of two or more of these solvents, or a commercially available thinner liquid can be used.

In addition, after the cleaning, post-baking may be performed in order to volatilize the rinse liquid. A temperature condition of the post-baking is preferably 80° C. to 300° C., more preferably 90° C. to 270° C., and still more preferably 100° C. to 250° C. The baking time is preferably 30 to 500 seconds and more preferably 60 to 240 seconds. The thickness of the undercoat agent layer 2 after the post-baking is preferably approximately 1 to 10 nm and more preferably approximately 2 to 7 nm.

Next, the layer 3 (BCP layer) containing the component (BCP) is formed on the undercoat agent layer 2.

The method of forming the BCP layer 3 on the undercoat agent layer 2 is not particularly limited, and a method of applying the resin composition for forming an etching mask pattern according to the above-described embodiment onto the undercoat agent layer 2 by a known method in the related art, such as spin coating or using a spinner, to form a coating film, and drying the coating film is an exemplary example.

The thickness of the BCP layer 3 may be a thickness sufficient to form the etching mask pattern, and is preferably 25 nm or more, more preferably 30 nm or more, and still more preferably 36 nm or more. As the upper limit of the thickness of the BCP layer 3, for example, 100 nm or less is an exemplary example, and 90 nm or less is preferable, 80 nm or less is more preferable, 70 nm or less is still more preferable, and 60 nm or less is particularly preferable. For example, in a case where the support 1 is an Si substrate, the thickness of the BCP layer 3 is adjusted to be preferably 25 to 100 nm, more preferably 30 to 90 nm, still more preferably 30 to 80 nm, and particularly preferably 30 to 60 nm.

### Step (ii)

In the step (ii), the BCP layer 3 formed on the support 1 is phase-separated.

By heating the support 1 after the step (i) to perform an annealing treatment, a phase-separated structure is formed such that at least a portion of the surface of the support 1 is exposed by selective removal of the block copolymer. That is, the structure body 3′ including a phase-separated structure which is phase-separated into a phase 3a and a phase 3b is produced on the support 1.

The annealing treatment is preferably performed under a temperature condition of equal to or higher than a glass transition temperature of the component (BCP) used and lower than a thermal decomposition temperature thereof. For example, in a case where the block copolymer is a polystyrene-poly(methyl methacrylate) (PS-PMMA) block copolymer (mass-average molecular weight: 5,000 to 100,000), the temperature is preferably 180° C. to 270° C. The heating time is preferably 30 to 3600 seconds.

In addition, it is preferable that the annealing treatment is performed in a gas having low reactivity, such as nitrogen.

With the method for manufacturing an etching mask pattern according to the embodiment described above, since the above-described resin composition for forming an etching mask pattern according to the embodiment is used, it is possible to obtain a structure body including a vertically-oriented phase-separated structure with a film thickness sufficient for forming an etching mask pattern (for example, a film thickness of 25 nm or more, and preferably a film thickness of 30 nm or more). Therefore, it is possible to manufacture an etching mask pattern using the structure body including the phase-separated structure.

### Optional Step

The method for producing a structure body including a phase-separated structure is not limited to the above-described embodiment, and may have a step (optional step) in addition to the steps (i) and (ii).

As the optional step, a step of selectively removing a phase formed of at least one kind of block among the first block and the second block constituting the component (BCP) from the BCP layer 3 (hereinafter, referred to as “step (iii)”), a guide pattern forming step, and the like are exemplary examples.

Regarding Step (iii)

In the step (iii), a phase formed of at least one kind of block among the first block and the second block constituting the above-described component (BCP) is selectively removed from the BCP layer which has been formed on the undercoat agent layer 2. As a result, an etching mask pattern is formed.

As a method of selectively removing the phase including any of the blocks, a method of performing an oxygen plasma treatment on the BCP layer, a method of performing a hydrogen plasma treatment on the BCP layer, and the like are exemplary examples.

For example, after the BCP layer containing the above-described component (BCP) is phase-separated, the BCP layer is subjected to an oxygen plasma treatment, a hydrogen plasma treatment, or the like, so that the phase including the first block is not selectively removed, and the phase including the second block is selectively removed.

FIG. 2 shows an exemplary embodiment of the step (iii).

In the embodiment shown in FIG. 2, in a case where the phase 3a is selectively removed and an etching mask pattern from the separated phase 3b is formed by performing an oxygen plasma treatment on the structure body 3′ produced on the support 1 in the step (ii). In this case, the phase 3b is a phase formed of the first block, and the phase 3a is a phase formed of the second block.

The etching mask pattern obtained as described above can be used for etching the support as it is, but a shape of the etching mask pattern on the support 1 can be changed by further heating.

Regarding the temperature conditions for the heating, it is preferable that the annealing treatment is performed at a temperature equal to or higher than a glass transition temperature of the block copolymer used and lower than a thermal decomposition temperature. In addition, the heating is preferably performed in a gas having low reactivity, such as nitrogen.

### Regarding Guide Pattern Forming Step

In the method for producing a structure body including a phase-separated structure, a step (guide pattern forming step) of forming a guide pattern on the undercoat agent layer may be provided before the step (i) and the step (ii) described above. As a result, it is possible to control an array structure of the phase-separated structure.

For example, in a case where the guide pattern is not provided, even for a block copolymer with which a random fingerprint-shaped phase-separated structure is formed, in a case where a groove structure of a resist film is provided on the surface of the undercoat agent layer, a phase-separated structure oriented along the grooves is obtained. According to such a principle, the guide pattern may be provided on the undercoat agent layer 2. In addition, in a case where a surface of the guide pattern has an affinity with any of the blocks constituting the above-described component (BCP), a phase-separated structure oriented in the direction perpendicular to the surface of the support is likely to be formed.

The guide pattern can be formed, for example, using a resist composition.

As the resist composition for forming the guide pattern, among resist compositions and modified products thereof, which are generally used for formation of a resist pattern, any one having the affinity with any of the blocks constituting the above-described component (BCP) can be appropriately selected and used. The resist composition may be any of a positive-type resist composition for forming a positive-type pattern in which the exposed part of the resist film is dissolved and removed, or a negative-type resist composition for forming a negative-type pattern in which the unexposed part of the resist film is dissolved and removed; but the resist composition is preferably a negative-type resist composition. As the negative-type resist composition, for example, a resist composition containing an acid generator, and a base material component in which solubility in a liquid developer containing an organic solvent is decreased by the action of an acid, and in which the base material component contains a resin component having a constitutional unit which is decomposed by the action of an acid to have increased polarity, is preferable.

After the resin composition for forming an etching pattern is poured on the undercoat agent layer on which the guide pattern has been formed, an annealing treatment is performed to induce phase separation. Therefore, the resist composition for forming the guide pattern is preferably a composition capable of forming a resist film having excellent solvent resistance and heat resistance.

### Example

Hereinafter, the present invention will be described in more detail with reference to examples, but the present invention is not limited to these examples.

### Synthesis of BCP Precursor: BCP Precursor (1)

All anionic polymerizations were carried out in an argon atmosphere. 30 mL of tetrahydrofuran (THF) and lithium chloride (LiCl) (21.2 mg, 0.500 mmol) were transferred into a 50 mL Schlenk tube and cooled to −78° C. in a Coolnics bath. Sec-butyllithium (Sec-BuLi) (1.05M hexane/cyclohexane solution) was added to the Schlenk tube until the color of the solution turned yellow. The Schlenk tube was removed from the Coolnics bath and warmed to room temperature until the colorless solution was obtained. The Schlenk tube was cooled again in a Coolnics bath to −78° C., and sec-BuLi (0.095 mL, 0.100 mmol) was added as an initiator. Styrene (1.03 mL, 9.04 mmol) was added thereto, and the mixture was stirred for 30 minutes. As a result, a bright orange colored solution was obtained. 1,1-diphenylethylene (DPE) (0.088 mL, 0.50 mmol) was added thereof, and the color of the solution turned deep red. After stirring for 30 minutes, a monomer mixture of methyl methacrylate (MMA) (0.80 mL, 7.50 mmol) and glycidyl methacrylate (GMA) (0.325 mL, 2.50 mmol) was added thereto, and the mixture was stirred for 30 minutes. The color of the solution turned from red to transparent. As a terminator, 3 mL of degassed methanol (MeOH) was added to the Schlenk tube to terminate the polymerization. The Schlenk tube was pulled up from the Coolnics bath, and the solution was introduced into MeOH to perform reprecipitation. The solid of the precipitate was filtered and then dried under reduced pressure at 40° C. to obtain a white powder of a BCP precursor (1) (1.76 g, 88% yield).

### Synthesis of Block Copolymer: BCP (1)

0.2 g of the BCP precursor (1) and THF (20 wt % solution) were placed into a 10 mL glass tube, and the mixture was immersed in an ice water tank. A 1 wt % lithium hydroxide (LiOH) aqueous solution (LiOH 0.05 molar equivalent/GMA unit) and 2,2,2-trifluoroethanethiol (2 molar equivalent/GMA unit) were added to the glass tube. After stirring the mixture at room temperature for 20 minutes, a reactor was set to 40° C., and the mixture was stirred for 3 hours to synthesize BCP (1). Residual reagents were removed by repeatedly performing precipitation with methanol or methanol/hexane several times, depending on the Mn and PHFMA fractions of the synthesized BCP (1). The product was dried under reduced pressure overnight at room temperature to obtain a white powder of the BCP (1). Mn and dispersity (PDI=Mw/Mn) of the BCP (1), measured by size-exclusion chromatography (SEC), were 23,000 g·mol-1 and 1.05.

¹H NMR (400 MHZ, Acetone-d₆, δ, ppm): 0.84 (s, α-CH₃, PMMA), 0.87 (s, α-CH₃, PMMA), 1.00 (s, α-CH₃, PMMA), 1.03 (s, α-CH₃, PHFMA), 1.23 to 1.73 (br, backbone, —CH₂—CH—, PS), 1.75 to 2.23 (br, backbone, —CH₂—CH—, PS; br, backbone, —CH₂—C(CH₃)—, PHFMA and PMMA), 2.78 to 3.00 (d, CH(OH)—CH₂—S—, PHFMA), 3.40 to 3.77 (s, —S—CH₂—CF3, PHFMA), 3.54 to 3.75 (s, —OCH₃, PMMA), 3.92 to 4.07 (d, —(C═O)O—CH₂—, PHFMA), 4.07 to 4.18 (m, —CH(OH)—, PHFMA) 4.50 to 4.72 (br, —CH(OH)—, PHFMA), 6.36 to 6.84 (m, o-aromatic, PS), 6.85 to 7.35 (m, m- and p-aromatic, PS)

### Synthesis of Block Copolymer: BCP (2)

A BCP precursor (2) was synthesized in the same manner as in the synthesis of the BCP precursor (1) described above, except that the use amount of styrene was changed to 2.71 mL (23.8 mmol), the use amount of MMA was changed to 0.91 mL (8.5 mmol), and the use amount of GMA was changed to 0.065 mL (0.5 mmol). Next, BCP (2) was synthesized in the same manner as in the BCP (1) described above, except that the BCP precursor (2) was used instead of the BCP precursor (1). Mn and dispersity (PDI=Mw/Mn) of the BCP (2), measured by size-exclusion chromatography (SEC), were 33,000 g·mol-1 and 1.05.

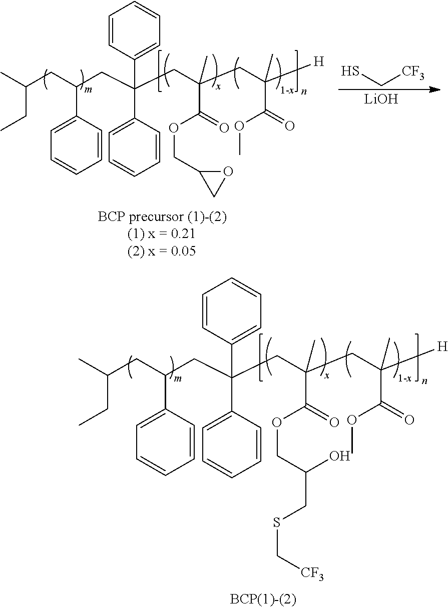

### Measurement of Volume of Each Block

mol % of each block in the block copolymer was calculated from the result of ¹H NMR analysis, and % by mass of each block was further calculated. Next, the % by mass of each block was divided by a density of each block to calculate a ratio of volume of each block. From the ratio of volume, the proportion of the volume of the polystyrene block to the total volume of the block copolymer was calculated. The density of each block was estimated by the atomic group contribution method (Fedors, R. F. Polym. Eng. Sci. 1974, 14, pp. 147 to 154). 1.05 g·m⁻³ was used as the density of the polystyrene block. 1.18 g·cm⁻³ was used as a density of a structure composed of the constitutional unit induced from methyl methacrylate. 1.43 g·cm⁻³ was used as a density of a structure composed of the constitutional unit induced from 2-hydroxy-3-(2,2,2-trifluoroethylsulfanyl) propyl methacrylate.

For each block copolymer synthesized as described above, the number-average molecular weight (Mn), the dispersity (PDI=Mw/Mn), the proportion (% by volume) of the volume of the polystyrene block (PS) to the total volume of the block copolymer, and the value of x in the reaction formula are summarized in Table 1.

TABLE 1

| | Mn | PDI | % by volume of PS | x |
|---|---|---|---|---|
| BCP (1) | 23000 | 1.05 | 51 | 0.21 |
| BCP (2) | 33000 | 1.05 | 71 | 0.05 |

### Preparation of Undercoat Agent

Each component shown in Table 2 was mixed and dissolved to prepare each of undercoating agents NL-1 to NL-3 (solid content concentration: 1% by mass).

TABLE 2

| | | Organic solvent | Contact angle of |
|---|---|---|---|
| | Polymer | component | water (°) |
| NL-1 | (P)-1 | (S)-1 | 72 |
| | [100] | [9900] | |
| NL-2 | (P)-2 | (S)-1 | 75 |
| | [100] | [9900] | |
| NL-3 | (P)-3 | (S)-1 | 77 |
| | [100] | [9900] | |

In Table 2, each abbreviation has the following meaning. A numerical value in the brackets is a blending amount (part by mass). The number-average molecular weight (Mn) of each polymer was determined by size-exclusion chromatography (SEC). The copolymerization compositional ratio (proportion (molar ratio) of each constitutional unit in a structural formula) of each polymer was determined by ¹³C-NMR.
(P)-1: polymer represented by Chemical Formula (P-1); Mn=24,000, l/m/n=39/56/5
(P)-2: polymer represented by Chemical Formula (P-1); Mn=28,000, l/m/n=49/46/5
(P)-3: polymer represented by Chemical Formula (P-1); Mn=30,000, l/m/n=61/34/5
(S)-1: propylene glycol monomethyl ether acetate (PGMEA)

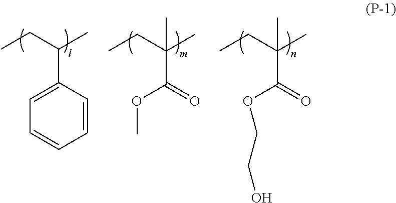

In Table 2, the “Contact angle of water) (°” was measured as follows.

An undercoat agent layer was formed by the same method as in “Formation of undercoat agent layer” described later. Water (2 μL) was dropped onto a surface of the undercoat agent layer, and a contact angle (static contact angle) was measured using a DROP MASTER-700 (product name, manufactured by Kyowa Interface Science Co., Ltd.).

### Examples 1 to 3 and Comparative Example 1

### Preparation of Resin Composition for Forming Etching Mask Pattern

Each component shown in Table 3 was mixed and dissolved to prepare a resin composition for forming an etching mask pattern (solid content concentration: 1.25% by mass) of each example.

TABLE 3

| | | | | Organic |
|---|---|---|---|---|
| | Block | Homopolymer | Homopolymer | solvent |
| | copolymer | (PS) | (PMMA) | component |
| Comparative | BCP-1 | — | — | (S)-1 |
| Example 1 | [100] | | | [7900] |
| Example 1 | BCP-1 | PS-2k | PMMA-2k | (S)-1 |
| | [100] | [5.0] | [5.0] | [8690] |
| Example 2 | BCP-1 | PS-2k | PMMA-2k | (S)-1 |
| | [100] | [10.0] | [10.0] | [9480] |
| Example 3 | BCP-1 | PS-2k | PMMA-2k | (S)-1 |
| | [100] | [15.0] | [15.0] | [10270] |

In Table 3, each abbreviation has the following meaning. Numerical values in the brackets are blending amounts (part by mass).
BCP-1: BCP (1) described above
PS-2k: polystyrene; the number-average molecular weight (Mn) measured by size-exclusion chromatography (SEC) was 2,000
PMMA-2k: poly(methyl methacrylate); the number-average molecular weight (Mn) measured by size-exclusion chromatography (SEC) was 2,000
(S)-1: PGMEA

### Production of Etching Mask Pattern (1)

After forming an undercoat agent layer on a wafer with the above-described undercoat agent NL-1, an etching mask pattern was obtained by a production method including the following steps (i) to (iii), using the resin composition for forming an etching mask pattern of each of the above-described examples.

### Formation of Undercoat Agent Layer:

The above-described undercoat agent NL-1 was spin-coated on a silicon substrate, and then heated in an air atmosphere at 250° C. for 5 minutes. Next, rinsing was performed with a mixed solvent of propylene glycol monomethyl ether (PGME)/propylene glycol monomethyl ether acetate (PGMEA) (PGME/MGMEA=7/3 (mass ratio)). Next, the product was heated at 100° C. for 1 minute. As a result, an undercoat agent layer having a film thickness of 5 nm and formed of the above-described undercoat agent NL-1 was formed on the surface of the substrate.

### Step (i):

The resin composition for forming an etching mask pattern of each example was spin-coated on the above-described undercoat agent layer such that a film thickness was 36 nm, thereby forming a resin composition layer (a layer containing a block copolymer).

### Step (ii):

The resin composition layer formed on the above-described undercoat agent layer was pre-baked at 90° C. for 60 seconds in a nitrogen atmosphere, and then annealed at 240° C. for 5 minutes in a nitrogen atmosphere to form a phase-separated structure.

Step (iii):

Oxygen plasma treatment (200 mL/min, 40 Pa, 40° C., 200 W, 10 seconds) was performed on the substrate on which the phase-separated structure had been formed using TCA-3822 (manufactured by TOKYO OHKA KOGYO CO., LTD.), and thus a PMMA phase was selectively removed.

### Evaluation of Resolution

The surface (in the phase-separated state) of the obtained substrate was observed with a length-measuring SEM (scanning electron microscope, trade name: CG6300, manufactured by Hitachi High-Tech Corporation) to confirm formation of a microphase-separated structure (lamellar structure).

As a result of such observation, resolution was evaluated based on the following evaluation standard. The results are shown in Table 4 as “Resolution”.

### Evaluation Standard

A: microphase-separated structure without breaking was observed over the entire surface.
B: breaking was observed in a part of the microphase-separated structure.
C: microphase-separated structure was not observed.

### Evaluation of Vertical Orientation

The surface (in the phase-separated state) of the obtained substrate was observed with a length-measuring SEM (scanning electron microscope, trade name: CG6300, manufactured by Hitachi High-Tech Corporation).

As a result of the observation, vertical orientation of the etching pattern was evaluated based on the following evaluation standard. The results are shown in Table 3 as “Vertical orientation”.

### Evaluation Standard

A: vertical lamella pattern was formed on the entire surface.
B: vertical lamella pattern was partially formed.
C: terrace structure or no pattern was formed.

TABLE 4

| | Resolution | Vertical orientation |
|---|---|---|
| Comparative | C | C |
| Example 1 | | |
| Example 1 | A | A |
| Example 2 | A | A |
| Example 3 | A | A |

From the results shown in Table 4, in Examples 1 to 3, it was possible to form an etching mask pattern having favorable resolution and vertical orientation. On the other hand, in Comparative Example 1, it was not possible to form a vertical lamella pattern, and it was not possible to form an etching mask pattern.

### Examples 4 to 8 and Comparative Examples 2 to 4

### Preparation of Resin Composition for Forming Etching Mask Pattern

Each component shown in Table 5 was mixed and dissolved to prepare a resin composition for forming an etching mask pattern (solid content concentration: 1.25% by mass) of each example.

TABLE 5

| | | | | Organic |
|---|---|---|---|---|
| | Block | Homopolymer | Homopolymer | solvent |
| | copolymer | (PS) | (PMMA) | component |
| Example 4 | BCP-1 | PS-2k | PMMA-2k | (S)-1 |
| | [100] | [25.0] | [25.0] | [11850] |
| Example 5 | BCP-1 | PS-2k | PMMA-2k | (S)-1 |
| | [100] | [50.0] | [50.0] | [15800] |
| Example 6 | BCP-1 | PS-1.5k | PMMA-1.5k | (S)-1 |
| | [100] | [15.0] | [15.0] | [10270] |
| Example 7 | BCP-1 | PS-2k | — | (S)-1 |
| | [100] | [30.0] | | [10270] |
| Example 8 | BCP-1 | PS-2k | PMMA-2k | (S)-1 |
| | [100] | [21.5] | [7.5] | [10270] |
| Comparative | BCP-1 | PS-3k | PMMA-3k | (S)-1 |
| Example 2 | [100] | [15.0] | [15.0] | [10270] |
| Comparative | BCP-1 | PS-5k | PMMA-5k | (S)-1 |
| Example 3 | [100] | [15.0] | [15.0] | [10270] |
| Comparative | BCP-1 | — | PMMA-2k | (S)-1 |
| Example 4 | [100] | | [30.0] | [10270] |

In Table 5, each abbreviation has the following meaning. A numerical value in the brackets is a blending amount (part by mass).
BCP-1: BCP (1) described above
PS-2k: polystyrene; the number-average molecular weight (Mn) measured by size-exclusion chromatography (SEC) was 2,000
PS-1.5k: polystyrene; the number-average molecular weight (Mn) measured by size-exclusion chromatography (SEC) was 1,500
PS-3k: polystyrene; the number-average molecular weight (Mn) measured by size-exclusion chromatography (SEC) was 3,000
PS-5k: polystyrene; the number-average molecular weight (Mn) measured by size-exclusion chromatography (SEC) was 5,000
PMMA-2k: poly(methyl methacrylate); the number-average molecular weight (Mn) measured by size-exclusion chromatography (SEC) was 2,000
PMMA-1.5k: poly(methyl methacrylate); the number-average molecular weight (Mn) measured by size-exclusion chromatography (SEC) was 1,500
PMMA-3k: poly(methyl methacrylate); the number-average molecular weight (Mn) measured by size-exclusion chromatography (SEC) was 3,000
PMMA-5k: poly(methyl methacrylate); the number-average molecular weight (Mn) measured by size-exclusion chromatography (SEC) was 5,000
(S)-1: PGMEA

### Production of Etching Mask Pattern (2)

An etching mask pattern was formed by the same method as in Production of etching mask pattern (1), except that the above-described undercoat agent NL-1 or NL-2 was used as the undercoat agent.

### Evaluation of Resolution

The resolution of the etching pattern formed of the resin composition for forming an etching mask pattern of each example was evaluated by the same method as described above. The results are shown in Table 6 as “Resolution”.

### Evaluation of Vertical Orientation

The vertical orientation of the etching pattern formed of the resin composition for forming an etching mask pattern of each example was evaluated by the same method as described above. The results are shown in Table 6 as “Vertical orientation”.

TABLE 6

| | |
|---|---|
| Resolution | Vertical orientation |

| | NL-1 | NL-2 | NL-1 | NL-2 |
|---|---|---|---|---|
| Example 4 | A | A | A | A |
| Example 5 | B | B | A | B |
| Example 6 | A | A | A | A |
| Example 7 | A | A | A | A |
| Example 8 | A | A | A | A |
| Comparative | C | C | C | C |
| Example 2 | | | | |
| Comparative | C | C | C | C |
| Example 3 | | | | |
| Comparative | C | C | C | C |
| Example 4 | | | | |

From the results shown in Table 6, in Examples 4 to 8, it was possible to form an etching mask pattern having favorable resolution and favorable vertical orientation regardless of the undercoat agent used. On the other hand, in Comparative Example 1, in a case where any of the undercoat agents was used, it was not possible to form a vertical lamella pattern, and it was not possible to form an etching mask pattern.

### Examples 9 and 10 and Comparative Examples 5 to 7

### Preparation of Resin Composition for Forming Etching Mask Pattern

Each component shown in Table 7 was mixed and dissolved to prepare a resin composition for forming an etching mask pattern (solid content concentration: 1.25% by mass) of each example.

TABLE 7

| | | | | Organic |
|---|---|---|---|---|
| | Block | Homopolymer | Homopolymer | solvent |
| | copolymer | (PS) | (PMMA) | component |
| Example 9 | BCP-2 | PS-2k | PMMA-2k | (S)-1 |
| | [100] | [21.0] | [9.0] | [10270] |
| Example 10 | BCP-2 | PS-2k | PMMA-2k | (S)-1 |
| | [100] | [10.5] | [4.5] | [9085] |
| Comparative | BCP-2 | — | — | (S)-1 |
| Example 5 | [100] | | | [7900] |
| Comparative | BCP-3 | — | — | (S)-1 |
| Example 6 | [100] | | | [7900] |
| Comparative | BCP-3 | PS-2k | PMMA-2k | (S)-1 |
| Example 7 | [100] | [21.0] | [9.0] | [10270] |

In Table 7, each abbreviation has the following meaning. Numerical values in brackets are blending amounts (part by mass).

BCP-2: BCP (2) described above

BCP-3: block copolymer BCP (3) (PS-b-PMMA) shown below; for the block copolymer, the number-average molecular weight (Mn), the dispersity (PDI=Mw/Mn), and the proportion (% by volume) of the volume of the polystyrene block (PS) to the total volume of the block copolymer are summarized in Table 8

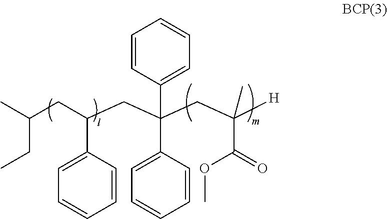

TABLE 8

| | Mn | PDI | % by volume of PS |
|---|---|---|---|
| BCP (3) | 50000 | 1.05 | 71 |

PS-2k: polystyrene; the number-average molecular weight (Mn) measured by size-exclusion chromatography (SEC) was 2,000
PMMA-2k: poly(methyl methacrylate); the number-average molecular weight (Mn) measured by size-exclusion chromatography (SEC) was 2,000
(S)-1: PGMEA

### Production of Etching Mask Pattern (3)

An etching mask pattern was formed by the same method as in Production of etching mask pattern (1), except that the above-described undercoat agent NL-3 was used as the undercoat agent, and the annealing temperature was changed to 220° C.

### Evaluation of Resolution

The surface (in the phase-separated state) of the obtained substrate was observed with a length-measuring SEM (scanning electron microscope, trade name: CG6300, manufactured by Hitachi High-Tech Corporation) to confirm formation of a microphase-separated structure (cylinder structure).

As a result of such observation, resolution was evaluated based on the following evaluation standard. The results are shown in Table 4 as “Resolution”.

### Evaluation Standard

A: microphase-separated structure without breaking was observed over the entire surface.
B: breaking was observed in a part of the microphase-separated structure.
C: microphase-separated structure was not observed.

### Evaluation of Vertical Orientation

The surface (in the phase-separated state) of the obtained substrate was observed with a length-measuring SEM (scanning electron microscope, trade name: CG6300, manufactured by Hitachi High-Tech Corporation).

As a result of the observation, vertical orientation of the etching pattern was evaluated based on the following evaluation standard. The results are shown in Table 9 as “vertical orientation”.

### Evaluation Standard

A: vertical cylinder pattern was formed on the entire surface.
B: vertical cylinder pattern was partially formed.
C: terrace structure or no pattern was formed.

TABLE 9

| | Resolution | Vertical orientation |
|---|---|---|
| Example 9 | A | A |
| Example 10 | A | A |
| Comparative | C | C |
| Example 5 | | |
| Comparative | C | C |
| Example 6 | | |
| Comparative | C | C |
| Example 7 | | |

From the results shown in Table 9, in Examples 9 and 10, it was possible to form an etching mask pattern having favorable resolution and vertical orientation. On the other hand, in Comparative Examples 5 to 7, it was not possible to form a vertical cylinder pattern, and it was not possible to form an etching mask pattern.

### Synthesis of Block Copolymer: BCP (4)

BCP (4) was synthesized in the same manner as in Synthesis of block copolymer: BCP (1) described above, except that ethanethiol was used instead of 2,2,2-trifluoroethanethiol. Mn and dispersity (PDI=Mw/Mn) of the BCP (4), measured by size-exclusion chromatography (SEC), were 23,000 g·mol-1 and 1.05.

¹H NMR (400 MHZ, CDCl₃, δ, ppm): 0.85 to 1.02 (α—CH₃, PMMA, PGEMA, —S—CH₂—CH₃, PGEMA), 1.23 to 1.69 (—CH₂—CH—, PS backbone), 1.74 to 2.02 (—CH₂—CH—, PS backbone, —CH₂—C(CH₃)—, PGEMA and PMMA), 2.63 (—CH(OH)—CH₂—S—CH₂—CH₃, PGEMA), 3.60 (—O—CH₃, PMMA), 3.99 (—(C═O)O—CH₂—CH(OH), PGEMA), 6.39 to 6.85 (o-aromatic, PS), 6.91 to 7.42 (p-, m-aromatic, PS)

### Synthesis of Block Copolymer: BCP (5)

BCP (5) was synthesized in the same manner as in Synthesis of block copolymer: BCP (2) described above, except that ethanethiol was used instead of 2,2,2-trifluoroethanethiol. Mn and dispersity (PDI=Mw/Mn) of the BCP (5), measured by size-exclusion chromatography (SEC), were 33,000 g·mol⁻¹ and 1.05.

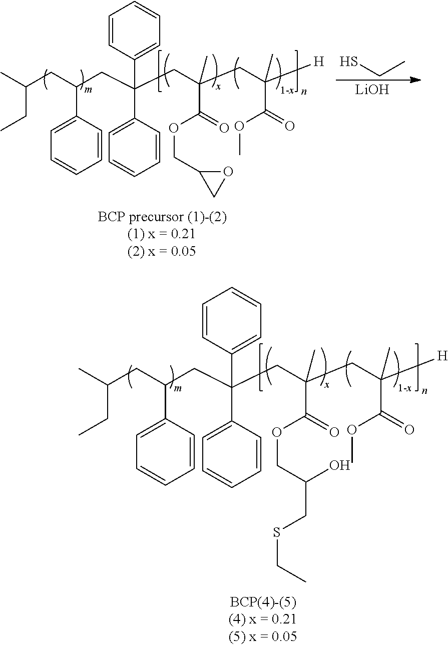

### Synthesis of Block Copolymer: BCP (6)

BCP (6) was synthesized in the same manner as in Synthesis of block copolymer: BCP (1) described above, except that 1-propanethiol was used instead of 2,2,2-trifluoroethanethiol. Mn and dispersity (PDI=Mw/Mn) of the BCP (6), measured by size-exclusion chromatography (SEC), were 23,000 g·mol⁻¹ and 1.05.

¹H NMR (400 MHZ, CDCl₃, δ, ppm): 0.85 to 1.02 (α—CH₃, PMMA, PGPMMA, —S—CH₂—CH₂—CH₃, PGPMA), 1.23 to 1.69 (—S—CH₂—CH₂—CH₃, PGPMA, —CH₂—CH—, PS backbone), 1.74 to 2.02 (—CH₂—CH—, PS backbone, —CH₂—C(CH₃)—, PGPMA and PMMA), 2.63 (—CH(OH)—CH₂—S—CH₂—CH₂—, PGPMA), 3.60 (—O—CH₃, PMMA), 3.99 (—(C═O)O—CH₂—CH(OH), PGPMA), 6.39 to 6.85 (o-aromatic, PS), 6.91 to 7.42 (p- and m-aromatic, PS)

### Synthesis of Block Copolymer: BCP (7)

BCP (7) was synthesized in the same manner as in Synthesis of block copolymer: BCP (2) described above, except that 1-propanethiol was used instead of 2,2,2-trifluoroethanethiol. Mn and dispersity (PDI=Mw/Mn) of the BCP (7), measured by size-exclusion chromatography (SEC), were 33,000 g·mol⁻¹ and 1.05.

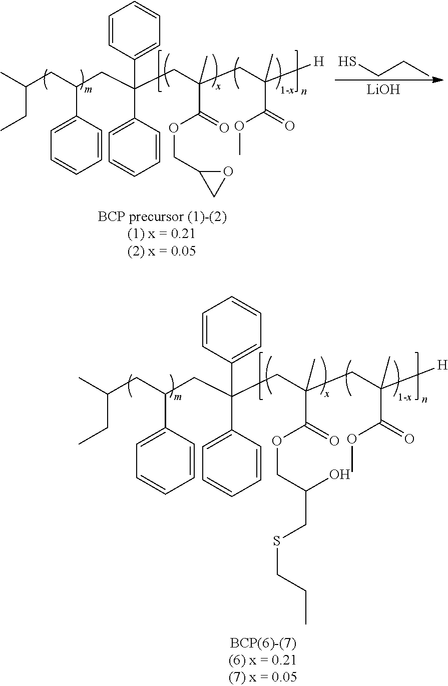

### Synthesis of Block Copolymer: BCP (8)

BCP (8) was synthesized in the same manner as in Synthesis of block copolymer: BCP (1) described above, except that 1-hexanethiol was used instead of 2,2,2-trifluoroethanethiol. Mn and dispersity (PDI=Mw/Mn) of the BCP (8), measured by size-exclusion chromatography (SEC), were 23,000 g·mol⁻¹ and 1.05.

¹H NMR (400 MHZ, CDCl₃, δ, ppm): 0.85 to 1.02 (α—CH₃, PMMA, PGHMA, —CH₂—CH₂—CH₃, PGHMA), 1.23 to 1.69 (—S—CH₂—CH₂—CH₂—CH₂—CH₂—, PGHMA, —CH₂—CH—, PS backbone), 1.74 to 2.02 (—CH₂—CH—, PS backbone, —CH₂—C(CH₃)—, PGHMA and PMMA), 2.63 (—CH(OH)—CH₂—S—CH₂—CH₂—, PGHMA), 3.60 (—O—CH₃, PMMA), 3.99 (—(C═O)O—CH₂—CH(OH), PGHMA), 6.39 to 6.85 (o-aromatic, PS), 6.91 to 7.42 (p- and m-aromatic, PS)

### Synthesis of Block Copolymer: BCP (9)

BCP (9) was synthesized in the same manner as in Synthesis of block copolymer: BCP (2) described above, except that 1-hexanethiol was used instead of 2,2,2-trifluoroethanethiol. Mn and dispersity (PDI=Mw/Mn) of the BCP (9), measured by size-exclusion chromatography (SEC), were 33,000 g·mol⁻¹ and 1.05.

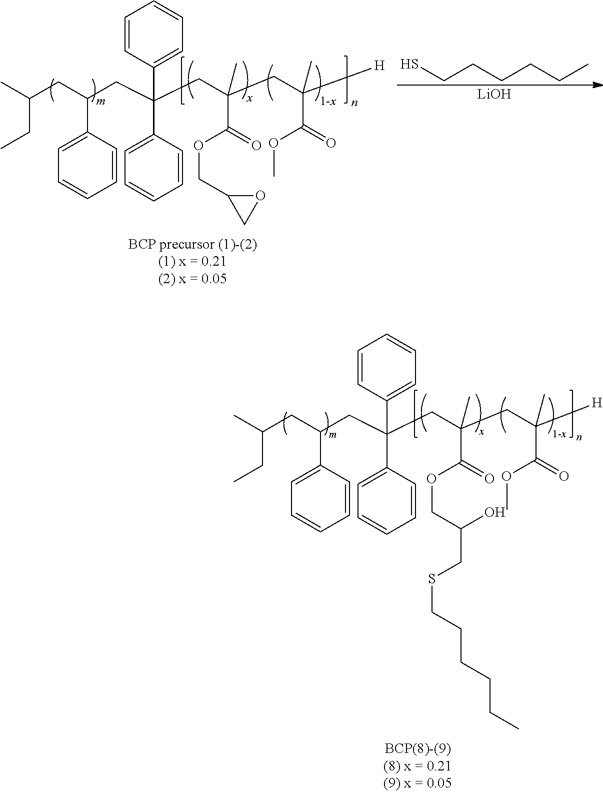

### Synthesis of Block Copolymer: BCP (10)

BCP (10) was synthesized in the same manner as in Synthesis of block copolymer: BCP (1) described above, except that cyclohexanethiol was used instead of 2,2,2-trifluoroethanethiol. Mn and dispersity (PDI=Mw/Mn) of the BCP (10), measured by size-exclusion chromatography (SEC), were 23,000 g· mol⁻¹ and 1.05.

¹H NMR (400 MHZ, CDCl₃, δ, ppm): 0.85 to 1.02 (α—CH₃, PMMA, PGCMA), 1.23 to 1.69 (—S—CH(CH₂—CH₂)—CH₂—CH₂—CH₂—, PGCMA, —CH₂—CH—, PS backbone), 1.74 to 2.02 (—S—CH(CH₂—CH₂)—CH₂—CH₂—CH₂—, PGCMA, —CH₂—CH—, PS backbone, —CH₂—C(CH₃)—, PGCMA and PMMA), 2.63 (—CH(OH)—CH₂—S—CH(CH₂—CH₂)—CH₂—CH₂—CH₂—, PGCMA), 3.60 (—O—CH₃, PMMA), 3.99 (—(C═O)O—CH₂—CH(OH), PGCMA), 6.39 to 6.85 (o-aromatic, PS), 6.91 to 7.42 (p- and m-aromatic, PS)

### Synthesis of Block Copolymer: BCP (11)

BCP (11) was synthesized in the same manner as in Synthesis of block copolymer: BCP (2) described above, except that cyclohexanethiol was used instead of 2,2,2-trifluoroethanethiol. Mn and dispersity (PDI=Mw/Mn) of the BCP (11), measured by size-exclusion chromatography (SEC), were 33,000 g· mol⁻¹ and 1.05.

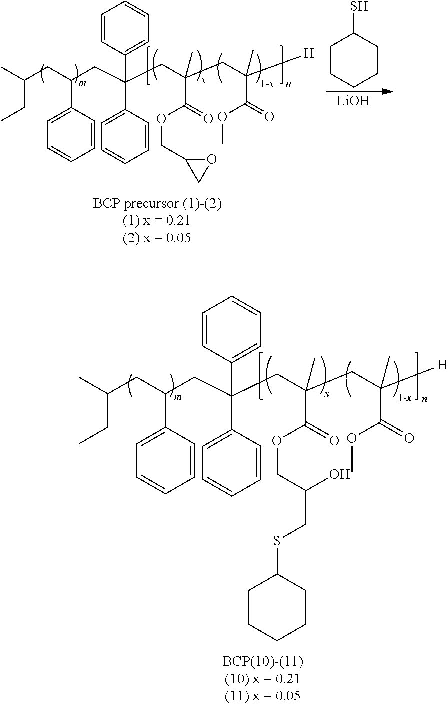

### Measurement of Volume of Each Block

A volume ratio of each block was calculated by the same method as described above. From the ratio of volume, the proportion of the volume of the polystyrene block to the total volume of the block copolymer was calculated by the same method as described above. In the block copolymers (4) to (11), the density of the structure composed of the constitutional unit corresponding to the constitutional unit (b2g) (a constitutional unit having a sulfide group) was set to 1.18 g·cm⁻³.

For the block copolymers (4) to (11) synthesized as described above, the number-average molecular weight (Mn), the dispersity (PDI=Mw/Mn), the proportion (% by volume) of the volume of the polystyrene block (PS) to the total volume of the block copolymer, and the value of x in the reaction formula are summarized in Table 10.

TABLE 10

| | Mn | PDI | % by volume of PS | x |
|---|---|---|---|---|
| BCP (4) | 23000 | 1.05 | 51 | 0.21 |
| BCP (5) | 33000 | 1.05 | 71 | 0.05 |
| BCP (6) | 23000 | 1.05 | 51 | 0.21 |
| BCP (7) | 33000 | 1.05 | 71 | 0.05 |
| BCP (8) | 23000 | 1.05 | 49 | 0.21 |
| BCP (9) | 33000 | 1.05 | 69 | 0.05 |
| BCP (10) | 23000 | 1.05 | 49 | 0.21 |
| BCP (11) | 33000 | 1.05 | 69 | 0.05 |

### Examples 11 to 30 and Comparative Examples 8 to 15

### Preparation of Resin Composition for Forming Etching Mask Pattern

Each component shown in Tables 11 and 12 was mixed and dissolved to prepare a resin composition for forming an etching mask pattern (solid content concentration: 1.25% by mass) of each example.

TABLE 11

| | | | | Organic |
|---|---|---|---|---|
| | Block | Homopolymer | Homopolymer | solvent |
| | copolymer | (PS) | (PMMA) | component |
| Comparative | BCP-4 | — | — | (S)-1 |
| Example 8 | [100] | | | [7900] |
| Example 11 | BCP-4 | PS-2k | PMMA-2k | (S)-1 |
| | [100] | [5.0] | [5.0] | [8690] |
| Example 12 | BCP-4 | PS-2k | PMMA-2k | (S)-1 |
| | [100] | [10.0] | [10.0] | [9480] |
| Example 13 | BCP-4 | PS-2k | PMMA-2k | (S)-1 |
| | [100] | [15.0] | [15.0] | [10270] |
| Comparative | BCP-6 | — | — | (S)-1 |
| Example 9 | [100] | | | [7900] |
| Example 14 | BCP-6 | PS-2k | PMMA-2k | (S)-1 |
| | [100] | [5.0] | [5.0] | [8690] |
| Example 15 | BCP-6 | PS-2k | PMMA-2k | (S)-1 |
| | [100] | [10.0] | [10.0] | [9480] |
| Example 16 | BCP-6 | PS-2k | PMMA-2k | (S)-1 |
| | [100] | [15.0] | [15.0] | [10270] |
| Comparative | BCP-8 | — | — | (S)-1 |
| Example 10 | [100] | | | [7900] |
| Example 17 | BCP-8 | PS-2k | PMMA-2k | (S)-1 |
| | [100] | [5.0] | [5.0] | [8690] |
| Example 18 | BCP-8 | PS-2k | PMMA-2k | (S)-1 |
| | [100] | [10.0] | [10.0] | [9480] |
| Example 19 | BCP-8 | PS-2k | PMMA-2k | (S)-1 |
| | [100] | [15.0] | [15.0] | [10270] |
| Comparative | BCP-10 | — | — | (S)-1 |
| Example 11 | [100] | | | [7900] |
| Example 20 | BCP-10 | PS-2k | PMMA-2k | (S)-1 |
| | [100] | [5.0] | [5.0] | [8690] |
| Example 21 | BCP-10 | PS-2k | PMMA-2k | (S)-1 |
| | [100] | [10.0] | [10.0] | [9480] |
| Example 22 | BCP-10 | PS-2k | PMMA-2k | (S)-1 |
| | [100] | [15.0] | [15.0] | [10270] |

TABLE 12

| | | | | Organic |
|---|---|---|---|---|
| | Block | Homopolymer | Homopolymer | solvent |
| | copolymer | (PS) | (PMMA) | component |
| Comparative | BCP-5 | — | — | (S)-1 |
| Example 12 | [100] | | | [7900] |
| Example 23 | BCP-5 | PS-2k | PMMA-2k | (S)-1 |
| | [100] | [21.0] | [9.0] | [10270] |
| Example 24 | BCP-5 | PS-2k | PMMA-2k | (S)-1 |
| | [100] | [10.5] | [4.5] | [9085] |
| Comparative | BCP-7 | — | — | (S)-1 |
| Example 13 | [100] | | | [7900] |
| Example 25 | BCP-7 | PS-2k | PMMA-2k | (S)-1 |
| | [100] | [21.0] | [9.0] | [10270] |
| Example 26 | BCP-7 | PS-2k | PMMA-2k | (S)-1 |
| | [100] | [10.5] | [4.5] | [9085] |
| Comparative | BCP-9 | — | — | (S)-1 |
| Example 14 | [100] | | | [7900] |
| Example 27 | BCP-9 | PS-2k | PMMA-2k | (S)-1 |
| | [100] | [21.0] | [9.0] | [10270] |
| Example 28 | BCP-9 | PS-2k | PMMA-2k | (S)-1 |
| | [100] | [10.5] | [4.5] | [9085] |
| Comparative | BCP-11 | — | — | (S)-1 |
| Example 15 | [100] | | | [7900] |
| Example 29 | BCP-11 | PS-2k | PMMA-2k | (S)-1 |
| | [100] | [21.0] | [9.0] | [10270] |
| Example 30 | BCP-11 | PS-2k | PMMA-2k | (S)-1 |
| | [100] | [10.5] | [4.5] | [9085] |

In Tables 11 and 12, each abbreviation has the following meaning. A numerical value in the brackets is a blending amount (part by mass).
BCP-4 to BCP-11: BCP (4) to BCP (11) described above
PS-2k: polystyrene; a number-average molecular weight (Mn) measured by size-exclusion chromatography (SEC) was 2,000
PMMA-2k: poly(methyl methacrylate); a number-average molecular weight (Mn) measured by size-exclusion chromatography (SEC) was 2,000
(S)-1: PGMEA

### Production of Etching Mask Pattern

An etching mask pattern was formed by the same method as in Production of etching mask pattern (1) described above.

### Evaluation of Resolution

The resolution of the etching pattern formed of the resin composition for forming an etching mask pattern of each example was evaluated by the same method as described in Examples 1 to 3 and Comparative Example 1 above. The results are shown in Tables 13 and 14 as “Resolution”.

### Evaluation of Vertical Orientation

The surface (in the phase-separated state) of the obtained substrate was observed with a length-measuring SEM (scanning electron microscope, trade name: CG6300, manufactured by Hitachi High-Tech Corporation).

As a result of the observation, vertical orientation of the etching pattern was evaluated based on the following evaluation standard. The results are shown in Tables 13 and 14 as “Vertical orientation”.

### Evaluation Standard

A: vertical lamella pattern was formed on the entire surface.
B: vertical lamella pattern was partially formed.
C: terrace structure or no pattern was formed.

TABLE 13

| | Resolution | Vertical orientation |
|---|---|---|
| Comparative | C | C |
| Example 8 | | |
| Example 11 | A | A |
| Example 12 | A | A |
| Example 13 | A | A |
| Comparative | C | C |
| Example 9 | | |
| Example 14 | A | A |
| Example 15 | A | A |
| Example 16 | A | A |
| Comparative | C | C |
| Example 10 | | |
| Example 17 | A | A |
| Example 18 | A | A |
| Example 19 | A | A |
| Comparative | C | C |
| Example 11 | | |
| Example 20 | A | A |
| Example 21 | A | A |
| Example 22 | A | A |

TABLE 14

| | Resolution | Vertical orientation |
|---|---|---|
| Comparative | C | C |
| Example 12 | | |
| Example 23 | A | A |
| Example 24 | A | A |
| Comparative | C | C |
| Example 13 | | |
| Example 25 | A | A |
| Example 26 | A | A |
| Comparative | C | C |
| Example 14 | | |
| Example 27 | A | A |
| Example 28 | A | A |
| Comparative | C | C |
| Example 15 | | |
| Example 29 | A | A |
| Example 30 | A | A |

From the results shown in Tables 13 and 14, in Examples 11 to 30, it was possible to form an etching mask pattern having favorable resolution and vertical orientation. On the other hand, in Comparative Examples 8 to 15, it was not possible to form a vertical lamella pattern, and it was not possible to form an etching mask pattern.

### Synthesis of Block Copolymer: BCP (12)

BCP (12) was synthesized in the same manner as in Synthesis of block copolymer: BCP (1) described above, except that 3-mercapto-1-hexanol was used instead of 2,2,2-trifluoroethanethiol. Mn and dispersity (PDI=Mw/Mn) of the BCP (12), measured by size-exclusion chromatography (SEC), were 23,000 g·mol⁻¹ and 1.05.

¹H NMR (400 MHZ, CDCl₃, δ, ppm): 0.71 to 1.05 (α—CH₃, PMMA and PGOMA, —S—CH—CH₂—CH₂—CH₃, PGOMA), 1.43 to 2.02 (—S—CH—CH₂—CH₂—CH₃, PGOMA, —S—CH—CH₂—CH₂—OH, PGOMA, —CH₂—CH—, PS backbone, —CH₂—C(CH₃)—, PGOMA and PMMA), 2.68 to 2.88 (—CH(OH)—CH₂—S—CH (-, PGOMA), 3.60 (—O—CH₃, PMMA), 3.73 (—S—CH—CH₂—CH₂—OH, PGOMA), 4.08 (—(C═O)O—CH₂—CH(OH), PGOMA), 6.39 to 6.85 (o-aromatic, PS), 6.91 to 7.42 (p-, m-aromatic, PS)

### Synthesis of Block Copolymer: BCP (13)

BCP (13) was synthesized in the same manner as in Synthesis of block copolymer: BCP (2) described above, except that 3-mercapto-1-hexanol was used instead of 2,2,2-trifluoroethanethiol. Mn and dispersity (PDI=Mw/Mn) of the BCP (13), measured by size-exclusion chromatography (SEC), were 33,000 g·mol⁻¹ and 1.05.

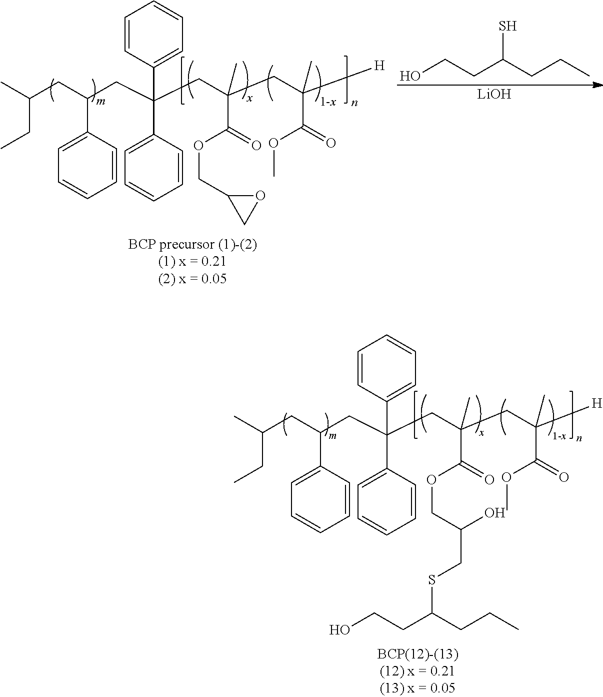

### Measurement of Volume of Each Block

A volume ratio of each block was calculated by the same method as described above. From the ratio of volume, the proportion of the volume of the polystyrene block to the total volume of the block copolymer was calculated by the same method as described above. In the block copolymers (12) and (13), the density of the structure composed of the constitutional unit corresponding to the constitutional unit (b2g) (a constitutional unit having a sulfide group) was set to 1.18 g·cm⁻³.

For the block copolymers (12) and (13) synthesized as described above, the number-average molecular weight (Mn), the dispersity (PDI=Mw/Mn), the proportion (% by volume) of the volume of the polystyrene block (PS) to the total volume of the block copolymer, and the value of x in the reaction formula are summarized in Table 15.

TABLE 15

| | Mn | PDI | % by volume of PS | x |
|---|---|---|---|---|
| BCP (12) | 23000 | 1.05 | 49 | 0.21 |
| BCP (13) | 33000 | 1.05 | 69 | 0.05 |

### Examples 31 to 35 and Comparative Examples 16 and 17

### Preparation of Resin Composition for Forming Etching Mask Pattern

Each component shown in Tables 16 and 17 was mixed and dissolved to prepare a resin composition for forming an etching mask pattern (solid content concentration: 1.25% by mass) of each example.

TABLE 16

| | | | | Organic |
|---|---|---|---|---|
| | Block | Homopolymer | Homopolymer | solvent |
| | copolymer | (PS) | (PMMA) | component |
| Comparative | BCP-12 | — | — | (S)-1 |
| Example 16 | [100] | | | [7900] |
| Example 31 | BCP-12 | PS-2k | PMMA-2k | (S)-1 |
| | [100] | [5.0] | [5.0] | [8690] |
| Example 32 | BCP-12 | PS-2k | PMMA-2k | (S)-1 |
| | [100] | [10.0] | [10.0] | [9480] |
| Example 33 | BCP-12 | PS-2k | PMMA-2k | (S)-1 |
| | [100] | [15.0] | [15.0] | [10270] |

TABLE 17

| | | | | Organic |
|---|---|---|---|---|
| | Block | Homopolymer | Homopolymer | solvent |
| | copolymer | (PS) | (PMMA) | component |
| Comparative | BCP-13 | — | — | (S)-1 |
| Example 17 | [100] | | | [7900] |
| Example 34 | BCP-13 | PS-2k | PMMA-2k | (S)-1 |
| | [100] | [21.0] | [9.0] | [10270] |
| Example 35 | BCP-13 | PS-2k | PMMA-2k | (S)-1 |
| | [100] | [10.5] | [4.5] | [9085] |

In Tables 16 and 17, each abbreviation has the following meaning. A numerical value in the brackets is a blending amount (part by mass).
BCP-12 and BCP-13: BCP (12) and BCP (13) described above
PS-2k: polystyrene; a number-average molecular weight (Mn) measured by size-exclusion chromatography (SEC) was 2,000
PMMA-2k: poly(methyl methacrylate); a number-average molecular weight (Mn) measured by size-exclusion chromatography (SEC) was 2,000
(S)-1: PGMEA

### Production of Etching Mask Pattern

In Comparative Example 16 and Examples 31 to 33, an etching mask pattern was formed by the same method as in Production of etching mask pattern (1) described above.

In Comparative Example 17 and Examples 34 and 35, an etching mask pattern was formed by the same method as in Production of etching mask pattern (3) described above.

### Evaluation of Resolution

The resolution of the etching pattern formed of the resin composition for forming an etching mask pattern of each example was evaluated by the same method as described in Examples 1 to 3 and Comparative Example 1 above. The results are shown in Tables 18 and 19 as “Resolution”.

### Evaluation of Vertical Orientation

The surface (in the phase-separated state) of the obtained substrate was observed with a length-measuring SEM (scanning electron microscope, trade name: CG6300, manufactured by Hitachi High-Tech Corporation).

As a result of the observation, vertical orientation of the etching pattern was evaluated based on the following evaluation standard. The results are shown in Tables 18 and 19 as “Vertical orientation”.

### Evaluation Standard

A: vertical lamella pattern was formed on the entire surface.
B: vertical lamella pattern was partially formed.
C: terrace structure or no pattern was formed.

TABLE 18

| | | Vertical |
|---|---|---|
| | Resolution | orientation |
| Comparative | C | C |
| Example 16 | | |
| Example 31 | A | A |
| Example 32 | A | A |
| Example 33 | A | A |

TABLE 19

| | | Vertical |
|---|---|---|
| | Resolution | orientation |
| Comparative | C | C |
| Example 17 | | |
| Example 34 | A | A |
| Example 35 | A | A |

From the results shown in Tables 18 and 19, in Examples 31 to 35, it was possible to form an etching mask pattern having favorable resolution and vertical orientation. On the other hand, in Comparative Examples 16 and 17, it was not possible to form a vertical lamella pattern, and it was not possible to form an etching mask pattern.

While preferred embodiments of the invention have been described and illustrated above, it should be understood that these are exemplary examples of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

### EXPLANATION OF REFERENCES

1: Support
2: Undercoat agent layer
3: BCP layer
3′: Structure body
3a: Phase
3b: Phase

What is claimed is:

1. A resin composition for forming an etching mask pattern, the resin composition comprising:
a block copolymer having a first block and a second block; and
a homopolymer having a number-average molecular weight of less than 3,000,
wherein the first block comprises a polymer consisting of a repeating structure of a constitutional unit represented by General Formula (b1),
the second block comprises a random copolymer consisting of a structure in which a constitutional unit represented by General Formula (b2m) and a constitutional unit represented by General Formula (b2g) are arranged in a disordered manner,
a proportion of a volume of the first block to a total volume of the first block and the second block is 20% to 80% by volume, and
the homopolymer comprises a polymer consisting of a repeating structure of the constitutional unit represented by General Formula (b1), 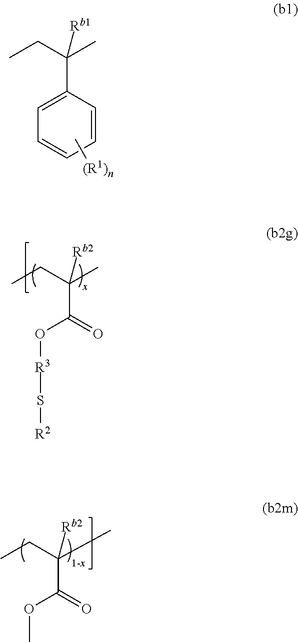
wherein, in Formula (b1), R¹ is an alkyl group, R^{b1} is a hydrogen atom or a methyl group, n is an integer of 0 to 5, and when n is an integer of 2 or more, a plurality of R¹'s may be the same or different from each other,
in Formula (b2g), R² is an alkyl group which may have a silicon atom, a fluorine atom, a carboxy group, an amino group, a cyano group, a hydroxy group, or a phosphoric acid group, and R³ is a linear or branched alkylene group having 1 to 10 carbon atoms, which may have a hydroxy group, and
in Formulae (b2g) and (b2m), R^{b2} is a hydrogen atom, an alkyl group having 1 to 5 carbon atoms, or a halogenated alkyl group having 1 to 5 carbon atoms, and a plurality of R^{b2}'s may be the same or different from each other, and x represents a molar ratio and is more than 0 and less than 1.

2. The resin composition for forming an etching mask pattern according to claim 1, wherein the homopolymer further comprises a polymer consisting of a repeating structure of the constitutional unit represented by General Formula (b2m).

3. The resin composition for forming an etching mask pattern according to claim 1, wherein the number-average molecular weight of the homopolymer is 1,000 or more.

4. The resin composition for forming an etching mask pattern according to claim 1, wherein an amount of the homopolymer is 10 to 50 parts by mass with respect to 100 parts by mass of the block copolymer.

5. A method for manufacturing an etching mask pattern, the method comprising:
applying the resin composition for forming an etching mask pattern according to claim 1 onto a support to form a layer containing a block copolymer; and
phase-separating the layer containing a block copolymer.

6. The method for manufacturing an etching mask pattern according to claim 5, wherein the layer containing a block copolymer is formed to have a film thickness of 25 nm or more.
